(19) United States
(12) Patent Application Publication
(10) Pub. No.: US 2014/0133221 A1
(43) Pub. Date: May 15, 2014

(54) Magnectic Structure

(71) Applicant: Russell Paul Cowburn, London (GB)

(72) Inventor: Russell Paul Cowburn, London (GB)

(73) Assignee: Cambridge Enterprise Limited, Cambridge (GB)

(21) Appl. No.: 13/992,683

(22) PCT Filed: Dec. 6, 2011
(86) PCT No.: PCT/GB11/52407

§ 371 Date: Aug. 20, 2013

(30) Foreign Application Priority Data
Dec. 7, 2010 (GB) 1020727.2

(51) Int. Cl. H01L 43/02; G11C 11/16; G11C 11/15

(52) U.S. Cl. CPC H01L 43/02; G11C 11/15; G11C 11/1675
USPC 365/158; 257/421

(57) ABSTRACT

A method of shifting information between magnetic layers in a thin film structure. The method can comprising applying a magnetic field to the thin film structure, the field having a magnitude sufficient to switch the magnetisation direction of a predetermined one of a pair of layers within the thin film structure when that pair of layers holds a frustration between two regions of different magnetisation direction order parameter within the thin film structure.

The work leading to this invention has received funding from the European Research Council under the European Union's seventh framework programme (fp7/2007-2013)/erc grant agreement No. 247368.

### FIELD

The present disclosure relates to magnetic structures and in particular but not exclusively to layered structures capable of maintaining alignment frustrations therein.

### BACKGROUND

In digital memory technologies, one of the main technological approaches to non-volatile memory uses FLASH memory. FLASH memory performs data storage by using charges floating in an oxide layer to provide individual data bit records. FLASH memory is known to have a number of drawbacks in terms of limited lifecycle (maximum read/write cycles), high power requirements, and slow read/write times. These drawbacks are the focus of a number of approaches in the mass storage application field including the use of DRAM caches to mask write latency, use of compression to avoid write amplification, and using over-provisioning to provide clean blocks for write operations.

In addition, and in view of the drawbacks of FLASH and similar solid state electronic memory technologies, there have been proposed some techniques for solid state magnetic memory. In such technologies, the data storage would be provided by some form of magnetic state retention in contrast to the electrical state retention of electronic memory. One such approach is that of Magnetoresistive RAM (MRAM). A number of MRAM techniques have been described, including the following.

U.S. Pat. No. 7,226,796 describes synthetic antiferromagnet structures for use in magnetic tunnel junctions in MRAM technology.

U.S. Pat. No. 6,898,112 describes a synthetic antiferromagnetic structure for magnetoelectronic devices.

“Magnetic Domain-Wall Racetrack Memory”, S. S. P. P. Parkin, M. Hayashi, L. Thomas, Science 320, 190 (2008); and U.S. Pat. Nos. 6,834,005, 6,898,132, 6,920,062, 7,031,178, and 7,236,386 describe different examples of a 3-dimensional non-volatile data storage device based on magnetic domain walls moving up shift registers comprising vertical tracks of magnetic material. All of the arrangements presented in these documents use spin transfer to propagate the domain walls. This technology does not use synthetic antiferromagnets at all, rather it uses a shift register arrangement for propagation of magnetic domains.

“Room temperature magnetic quantum cellular automata”, R. P. Cowburn, M. E. Welland, Science 287, 1466-1468 (2000) and “Magnetic nanodots for device applications”, R. P. Cowburn, Journal of Magnetism and Magnetic Materials. 242, 505-511 (2002) describe a soliton on a chain of magnetostatically parallel coupled ferromagnetic disks arranged adjacent one another in a single plane. This technology provided no synchronous mechanism for propagation, no possibility of putting a stream of bits in the same conduit, and no mechanism for unidirectional propagation of data.

PCT patent application publication no WO2002/041492 describes two systems: one is domain wall logic using magnetic nanowires, the other is the quantum cellular automata system described in Science 287, 1466-1468 (2000) mentioned above using magnetostatically coupled dots carrying a soliton.

Probing antiferromagnetic coupling between nanomagnets, R. P. Cowburn, Phys. Rev. B 65, 092409 (2002) describes chains of magnetostatically coupled ferromagnetic disks with an anisotropy. One of the conclusions of this work was that data could not be reliably propagated over any significant distance because the driving force decayed away. As with the other Cowburn works mentioned above, the disks were in the same plane.

U.S. Pat. No. 6,531,723 describes a magnetoresistance random access memory for improved scalability. This document introduces what is now known as “Toggle MRAM”. The document describes an MRAM cell with a synthetic antiferromagnet of N layers to hold a single data bit. This arrangement provides increased switching volume leading to improved scalability.

U.S. Pat. No. 6,545,906 describes a method of writing to a scalable magnetoresistance random access memory element. This has the same inventors as U.S. Pat. No. 6,531,723 and describes how a localised rotating field for the above N-layered SAF stack can be produced by delaying the current pulses through orthogonal word and bit lines.

Parish M C B, Forshaw M, IEE Proceedings-Circuits Devices and Systems 151 (5) 480-485 showed in a figure six repeat layers of a synthetic antiferromagnet, including ellipticity to create anisotropy, in the context of quantum cellular automata, as in Science 287, 1466-1468 (2000) mentioned above. The focus of this part of the paper is on keeping the layers coupled antiferromagnetically without error. The disclosure is thus very similar to Phys. Rev. B 65, 092409 (2002) mentioned above.

Property variation with shape in magnetic nanoelements, R. P. Cowburn, Invited Topical Review, J. Phys. D 33, R1-R16 (2000); Lateral interface anisotropy in nanomagnets, R. P. Cowburn, D. K. Koltsov, A. O. Adeyeye, M. E. Welland, J. Appl. Phys. 87, 7067-7069 (2000) and Superparamagnetism and the future of magnetic random access memory, R. P. Cowburn, J. Appl. Phys. 93, 9310 (2003), all provide examples of elliptical single layer magnetic structures to create shape anisotropy.

Additional work of R. P. Cowburn is set out in WO2010/055329. This document uses a column of antiferromagnetically coupled discs to produce a memory structure. The structure of this document has a column comprising a plurality of layers of magnetic material, each sized to adopt a single magnetic domain state, and a plurality of layers of non-magnetic material arranged as spacer layers between adjacent ones of the layers of magnetic material; such that successive magnetic layers in the column are magnetically antiparallel coupled. Thereby the column is operable to maintain therein a plurality of stable transitions of an order parameter of the magnetisations between the magnetic layers, the transitions having a chirality.

In the paper published by Albrecht et al, Journal of Applied Physics 97, 103910 (2005) “Magnetic dot arrays with multiple storage layers”, the authors propose a structure consisting two groups of Co—Pd multilayers for multi-bit storage. In this disclosure, the two groups are entirely uncoupled due to a thick interlayer and are separately addressable by virtue of their different coercivities. Thus this has no shift register action and is not scalable beyond two or three bits per stack.

In hard-disk magnetic recording the concepts of ‘exchange coupled composite’ (ECC) media, ‘exchange-spring’ media and ‘graded media’ have been introduced. Examples of these are found in the following publications
Hernandez, Kapoor and Victora, “Synthetic antiferromagnet for hard layer of exchange coupled composite media” Applied Physics Letters 90, 132505 (2007), doi:10.1063/1.2716860 (3 pages), Online Publication Date: 28 Mar. 2007.
Suess, D. et al, “Exchange spring media for perpendicular recording” Applied Physics Letters 87, 012504 (2005); doi:10.1063/1.1951053 (3 pages), Online Publication Date: 30 Jun. 2005
Victora, R. H., et al, “Composite Media for Perpendicular Magnetic Recording”, IEEE Trans. Magn. 41, 537 (2005)
Suess, D., “Multilayer exchange spring media for magnetic recording”, Applied Physics Letters 89, 113105 (2006); doi:10.1063/1.2347894 (3 pages), Online Publication Date: 11 Sep. 2006.
Suess, D. et al, “Thermal stability of graded exchange spring media under the influence of external fields”, Applied Physics Letters 92, 173111 (2008); doi:10.1063/1.2908052 (3 pages), Online Publication Date: 1 May 2008.
US2010/0062286 A1 (Suess, D.)

These approaches usually involve exchange coupling a low-coercivity and high-coercivity layer with the aim of reducing the strength of applied field required to write a bit without lowering the thermal stability of that bit.

### SUMMARY

Viewed from a first aspect, there can be provided a structure comprising a plurality of groups of magnetic layers, each group comprising three or more sequential physical properties, the plurality of groups arranged successively with the sequential physical properties of one group aligned in the same direction as the sequential physical properties of each adjacent group. The sequential physical properties of each group provide a resulting net switching field profile along the group that varies from an initial magnetic layer of the group toward a final magnetic layer of the group. Thus a structure can be provided having a predetermined propagation direction.

Viewed from another aspect, there can be provided a storage cell comprising the structure. Thus information storage may be provided.

Viewed from a further aspect, there can be provided a memory device comprising a plurality of storage cells. Thus bulk information storage may be provided.

Viewed from another aspect, there can be provided a state machine comprising a thin film multilayer structure having magnetic layers with resulting net switching field per layer following a profile gradient and antiparallel coupling between ones of the layers, configured to store state information by maintaining therein a stable frustration in an order parameter of magnetic alignments across the layers. Thus order parameter frustrations can be used to maintain state information.

Viewed from a further aspect, there can be provided a memory element comprising: a plurality of magnetic layers; and a plurality of non-magnetic layers between ones of the magnetic layers. Successive magnetic layers have a profile of resulting net switching fields following a decreasing gradient followed by an increasing gradient followed by a further decreasing gradient; and magnetic layer pairs following the decreasing gradient are antiparallel coupled and magnetic layer pairs following the increasing gradient are parallel coupled. Thus a managed profile of resulting net switching field can be provided.

Viewed from another aspect, there can be provided a method of shifting information between magnetic layers in a thin film structure, the method comprising: applying a magnetic field to the thin film structure, the field having a magnitude sufficient to switch the magnetisation direction of a predetermined one of a pair of layers within the thin film structure when that pair of layers holds a frustration between two regions of different magnetisation direction order parameter within the thin film structure. Thus such frustrations can be moved within the structure.

### BRIEF DESCRIPTION OF THE FIGURES

Specific embodiments will now be described by way of example only with reference to the accompanying figures in which:

FIG. 1 is a schematic illustration of propagation of a frustration along a coercivity gradient;

FIG. 2 is a schematic illustration of the frustration of FIG. 1 using in plane magnetised magnetic layers;

FIG. 3 is a schematic illustration of the frustration of FIG. 1 using out of plane magnetised magnetic layers;

FIG. 4 is a schematic illustration of the frustration of FIG. 1 using out of plane magnetised magnetic layers, after application of one cycle of external field;

FIG. 5 is a schematic representation of managing a coercivity gradient;

FIG. 6 is a schematic representation of propagation of a frustration along a coercivity gradient;

FIG. 7 is a schematic representation of using the propagation of FIG. 6 to implement the managed anisotropy gradient of FIG. 5;

FIG. 8 is a schematic representation of layer and inter-layer properties;

FIG. 9 shows an arrangement having alternating high and low anisotropy elements to implement a managed coercivity gradient;

FIG. 10 shows an arrangement having successive high, medium and low anisotropy elements to implement a managed profile of resulting net switching field;

FIG. 11 shows an arrangement having successive high, medium-high, medium-low and low anisotropy elements to implement a managed profile of resulting net switching field;

FIG. 12 shows an arrangement having successive medium, high, medium-high, medium-low and low anisotropy elements to implement a managed profile of resulting net switching field;

FIGS. 13A to 13F illustrate soliton propagation through the structure of FIG. 9;

FIG. 14 shows an arrangement having varied coupling strengths to implement a managed profile of resulting net switching field;

FIG. 15 shows an alternative arrangement having varied coupling strengths to implement a managed profile of resulting net switching field;

FIGS. 16A to 16F illustrate soliton propagation through the structure of FIG. 13;

FIG. 17 shows an arrangement having varied layer thicknesses to implement a managed profile of resulting net switching field;

FIGS. 18A to 18I illustrate soliton propagation at a high soliton density;

FIGS. 19A to 19C show an example of how solitons and/or order parameters can be used to store data;

FIG. 20 shows a first example of an approach to implement a structure having the managed profile of resulting net switching field 10;

FIG. 21 shows a second example of an approach to implement a structure having the managed profile of resulting net switching field 10;

FIG. 22 shows an example of an approach to implement a structure having the managed profile of resulting net switching field of FIG. 14;

FIG. 23 shows an example of an approach to implement a structure having the managed profile of resulting net switching field of FIG. 9;

FIG. 24 shows another example of an approach to implement a structure having the managed profile of resulting net switching field of FIG. 9;

FIG. 25 shows an example of an approach to implement a structure having the managed profile of resulting net switching field of FIG. 17;

FIGS. 26 and 27 shows examples of the operating margin and stability for a period-2 structure with alternating high and low anisotropy layers with alternating parallel and anti-parallel coupling;

FIGS. 28 and 29 show examples of the operating margin and stability for a period-3 structure with alternating parallel and anti-parallel coupling and varying coupling strength magnitudes;

FIGS. 30 and 31 show examples of the operating margin and stability for a period-3 structure with varying layer thicknesses;

FIG. 32 schematically illustrates a layer structure having a managed profile of resulting net switching field using alternating thickness, coercivity and exchange coupling;

FIG. 33 illustrates experimentally obtained (antiparallel) exchange fields as a function of ruthenium spacer layer for the structure of FIG. 32;

FIG. 34 illustrates hysteresis loops from two magnetic layers with different spacer thicknesses;

FIG. 35 illustrates coercivity as a function of magnetic layer thickness;

FIGS. 36A and 36B show examples of a data storage device using multiple layered structures;

FIG. 37 shows an example of a soliton injection or detection device;

FIG. 38 shows another example of a soliton injection or detection device; and

FIGS. 39A to 39C illustrate non-symmetry of inversion.

While the invention is susceptible to various modifications and alternative forms, specific embodiments are shown by way of example in the drawings and are herein described in detail. It should be understood, however, that drawings and detailed description thereto are not intended to limit the invention to the particular form disclosed, but on the contrary, the invention is to cover all modifications, equivalents and alternatives falling within the spirit and scope of the present invention as defined by the appended claims.

### DESCRIPTION

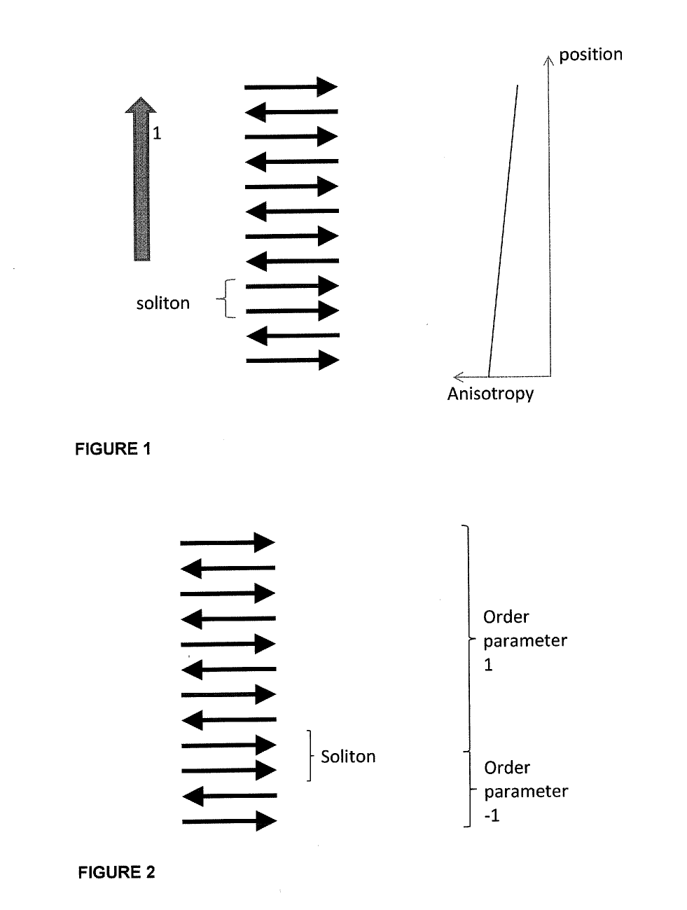

Examples of magnetic structures and methods of operating and utilising the same will now be described with reference to FIGS. 1 to 20.

The present disclosure relates to maintenance and propagation of order parameter frustrations within a structure having a number of magnetic layers. An example of a structure having a plurality of magnetic layers and how the order parameter of the magnetisations can be altered by a frustration is illustrated in FIG. 1.

In FIG. 1, there is shown schematically a layered structure made up of a number of layers of magnetic material, each having a magnetisation direction (or magnetic moment) indicated by an arrow. Each layer has an easy axis of anisotropy that encourages the magnetisation direction to fall along that axis, with the magnetisation direction being one or other way along the axis. There is also shown in the form of a graph that the inherent anisotropy of each magnetic layer is lower than that of its predecessor when viewing the layers in the direction indicated by the arrow 1.

In this arrangement, each layer is magnetically antiparallel coupled to each adjacent layer. This means that each layer tends to adopt a magnetisation field direction opposite to that of each of neighbouring layer. These magnetisation field directions are indicated by the arrows representing each layer. Although, for the sake of simplicity of representation, the magnetisation field direction are shown as being roughly parallel to plane of each layer, it is also possible to create the structure using materials that have out of plane magnetisation field directions.

Also illustrated in FIG. 1 is a frustration in magnetisation alignment. Thus, in this example of antiparallel coupling between layers, two adjacent layers are forced to adopt a parallel alignment in their magnetisation alignments.

Away from the frustration, each magnetic layer is in a low-energy environment, i.e. each of its two nearest neighbours is magnetised anti-parallel to itself. At the frustration, however, there are two magnetic layers which are in a frustrated state—each has one neighbour that is magnetised parallel to it (high energy) and one neighbour that is magnetised anti-parallel to it (low energy). If one of the frustrated disks were to have its magnetisation reversed, then the other frustrated disk would no longer be frustrated, but instead the frustration would move by one magnetic layer and a previously unfrustrated layer would now be frustrated. This region of frustration 12 is:
mobile (by reversing the magnetisation of a frustrated disk);
localised (away from the frustration each disk is in a stable, low-energy state);
persistent (to remove the frustration, half of the disks in the stack would have to be reversed, equivalent to moving the frustration all the way to one end of the stack and allowing it to fall out of the end).

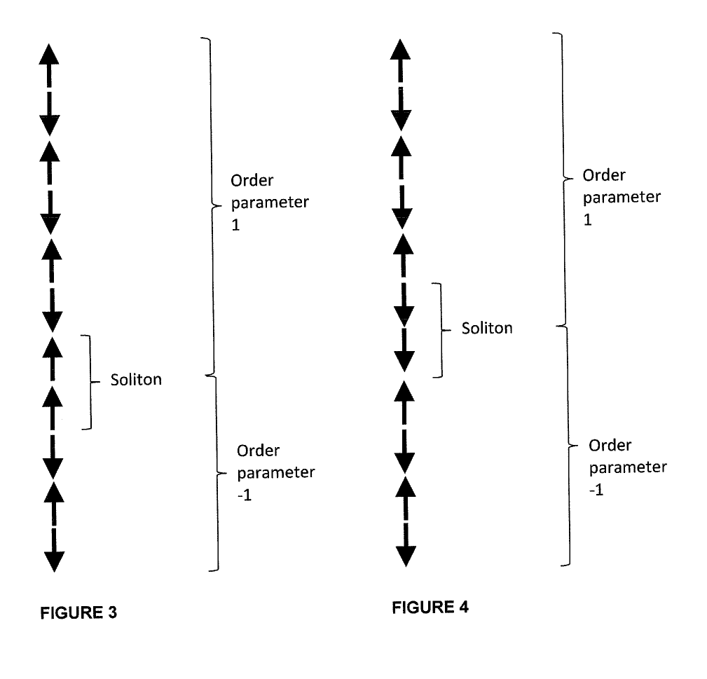

These are the general condition for a topological soliton. It is a kink soliton as the order parameter changes in passing through the soliton. The order parameter is further illustrated and discussed with reference to FIGS. 2 and 3 below.

A general discussion of topological magnetic solitons can be found in “Dynamics of Topological Magnetic Solitons, experiment and theory” V. G. Bar'yakhtor, M. V. Chetkin, B. A. Ivanov, S. N. Gadetskii, Springer Tracts in Modern Physics, Vol. 129, 1994, ISBN 3-540-56935-9 and 0-387-26935-9.

To propagate this soliton through the layers of FIG. 1, an oscillating or pulsed magnetic field can be applied, having an effect in the direction of arrow 1. By having the magnetic layers arranged according to the anisotropy gradient shown in the graph of FIG. 1, the soliton can be reliably propagated in the direction of arrow 1 as the energy barrier to switching the magnetisation direction is lower for the next layer down the gradient from the soliton than that of the next layer up the gradient from the soliton. Thus the direction of propagation is controlled and a reliable propagation can be effected. In addition, the propagation is synchronous in that each soliton moves one layer per half-cycle or pulse of applied field as illustrated by arrow 1 and if multiple solitons are held in the structure, each soliton moves the same amount on each pulse.

With reference to FIG. 2, an example is shown of successive antiparallel coupled magnetic layers with a soliton dividing the arrangement into two regions. The region on one side of the soliton has an order parameter value 1 and the region on the other side of the soliton has an order parameter value −1. The actual value of the order parameter is set according to a definition selected for a given implementation and can be the reverse of that indicated in FIG. 2. Also, the order parameter values can be given any appropriate values to distinguish between the two possible order states. In addition to the example of values 1 and −1, other examples such as 0 and 1, 1 and 2, A and B, L and R, or U and D could be used.

As can be seen in FIG. 2, the two different order parameter regions represent a reversal of magnetisation directions in each layer of the region relative to the other order parameter region. If, for example, order parameter region 1 is defined as a region in which all even-numbered layers have magnetisation in a first direction and all odd-numbered layers have magnetisation in a second direction opposite to the first direction, then order parameter region 2 would be a region in which all even-numbered layers have magnetisation in the second direction and all odd-numbered layers have magnetisation in the first direction.

FIG. 3 is similar to FIG. 2, but where FIG. 2 illustrated in-plane magnetisation directions for the magnetic layers, FIG. 3 instead illustrates out-of-plane magnetisation directions. Despite this alteration in magnetisation direction axes, the order parameter regions discussions relating to FIG. 2 still apply such that the arrangement shown in FIG. 3 has a soliton which is a divider between regions of different order parameter.

As mentioned above, the soliton is reliably propagated under the influence of an oscillating or pulsed magnetic field having sufficient intensity along the longitudinal axis of the layered structure to overcome the intrinsic anisotropy of an individual layer. Every half-cycle or pulse of the field acting in the propagation direction of the structure (illustrated by arrow 1 in FIG. 1) moves the soliton by one layer position in the propagation direction.

The reason that this happens is as follows. Both of the layers in which a given soliton resides have approximately net zero exchange field from their nearest neighbours as they each have one neighbour that has its magnetisation direction parallel aligned and one neighbour that has its magnetisation direction antiparallel aligned. Thus the switching field strength required for each of the layers in the soliton is just that necessary to overcome the intrinsic anisotropy of the layer. As the layers have the anisotropy gradient illustrated in FIG. 1, this provides that one layer has lower anisotropy than the other. Thus in the presence of the applied magnetic field acting along the longitudinal axis of the structure, the layer with the lower anisotropy will switch alignments before the layer with the higher anisotropy. Once the lower anisotropy layer has switched alignments, that layer becomes the higher anisotropy layer in a new soliton position and the original higher anisotropy layer is no longer carrying the soliton. This is illustrated in FIG. 4, which shows the same layer structure as FIG. 3 after one cycle of applied field. Given that the anisotropy gradient starts with the highest coercivity layer at the bottom of the figure, it is seen that after one half-cycle of applied field, the soliton has shifted one layer position down the gradient (up the page).

Whilst the approach described with reference to FIGS. 1 to 4 is certainly susceptible of application in a useful device, it will be appreciated that a downward gradient is not indefinitely extendable. There are practical limits imposed by materials properties on the highest and lowest anisotropies that can be used and thus the number of layers available in such a structure is likely in practice to be limited to less than ten layers. Thus, the present disclosure also presents an approach for resetting the anisotropy gradient to allow much larger numbers of layers to be utilised.

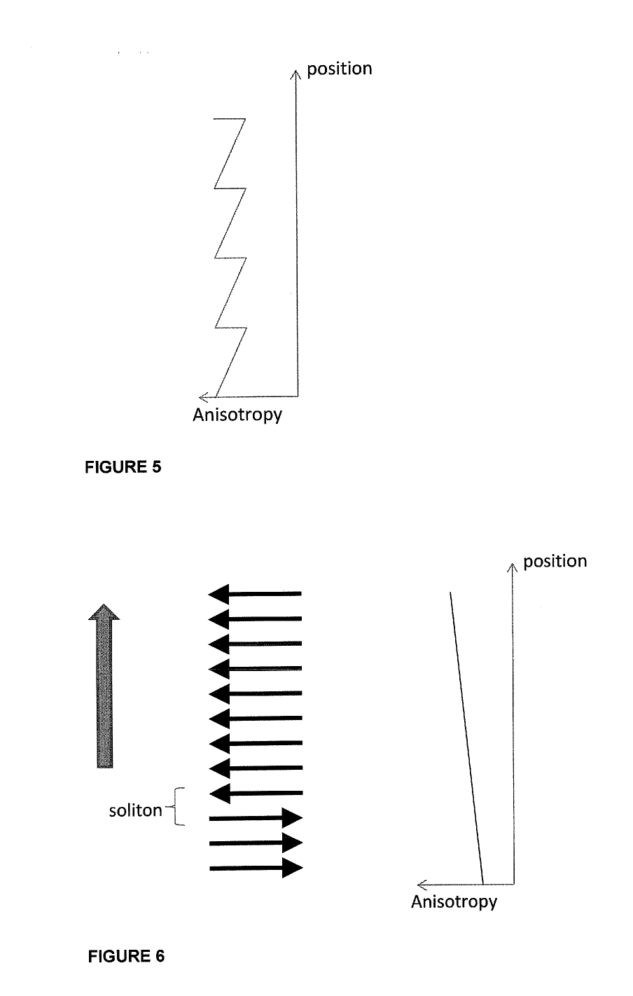

An example schematic representation of resetting the anisotropy gradient is shown in FIG. 5. This saw-tooth type pattern provides a number of regions of declining inherent layer anisotropy separated by regions of increasing anisotropy. Thus regions of declining anisotropy can be used as described above and then the anisotropy can be reset to a level where a reducing gradient can be restarted. This type of pattern is termed herein a managed anisotropy gradient.

In order to pass the soliton up the reverse slopes of the managed anisotropy gradient (i.e. up a region of increasing anisotropy), an alternative technique is required, as simply insetting an increasing anisotropy region into the structure discussed above with reference to FIGS. 1 to 3 would cause the soliton to stall at the increasing anisotropy region. The soliton would remain tied to the lowest anisotropy layer and oscillate (switching every cycle or pulse of applied field) between the second lowest anisotropy layer back along the decreasing anisotropy gradient region and the next highest anisotropy layer forwards along the increasing anisotropy gradient region.

A suitable approach for dealing with the increasing anisotropy regions of the managed anisotropy gradient is now discussed with reference to FIG. 6. As shown in FIG. 6, a soliton will propagate up an increasing anisotropy gradient upon application of an external field cycle or pulse acting in the direction of the increasing anisotropy if the layers are parallel coupled magnetic layers. In this example, as the default coupling of the layers is parallel, the soliton sits across a pair layers which are forced by the presence of the soliton to have antiparallel aligned magnetisation directions.

As with the situation illustrated with reference to FIG. 1 for antiparallel coupled layers, at the soliton there are two magnetic layers which are in a frustrated state—each has one neighbour that is magnetised parallel (the default alignment) to it and one neighbour that is magnetised anti-parallel to it. If one of the frustrated disks were to have its magnetisation reversed, then the other frustrated disk would no longer be frustrated, but instead the frustration would move by one magnetic layer and a previously unfrustrated layer would now be frustrated. Thus again this is:
mobile (by reversing the magnetisation of a frustrated disk);
localised (away from the frustration each disk is in a stable, low-energy state);
persistent (to remove the frustration, half of the disks in the stack would have to be reversed, equivalent to moving the frustration all the way to one end of the stack and allowing it to fall out of the end).

Thus again there is a topological soliton. It is a kink soliton as the order parameter changes in passing through the soliton. The discussion of order parameter presented with reference to FIGS. 2 and 3 above continues to apply except that in each order parameter region, all layers have the same alignment of magnetisation and the soliton bounds these regions by providing a region of antiparallel magnetisation alignment.

To propagate this soliton through the layers of FIG. 6, an oscillating or pulsed magnetic field can be applied, having an effect in the direction of arrow 1. By having the magnetic layers arranged according to the anisotropy gradient shown in the graph of FIG. 1, the soliton can be reliably propagated in the direction of arrow 1 as an applied field will tend to flip the alignment of the soliton layer furthest up the gradient, thus moving the soliton up by one layer. However, this propagation is asynchronous as each half-cycle or pulse of applied field will drive the soliton all the way to the end of the stack.

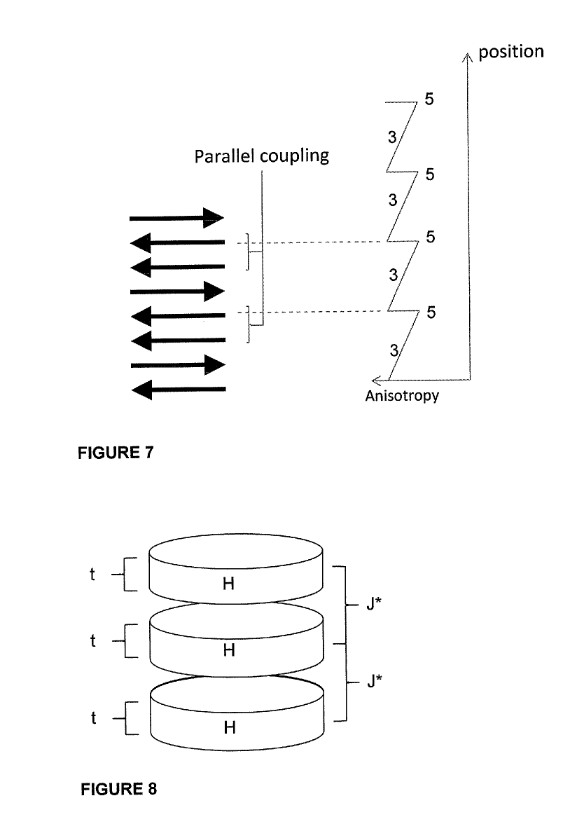

The present disclosure recognises the respective strengths and weaknesses of the two different structures described above and proposes an approach for utilising a combined approach which enables a useful and workable structure to be established. This combined approach uses the managed anisotropy gradient discussed with reference to FIG. 5 above and uses the differing properties of different layer coupling types to implement such a managed gradient. In other words, a structure can comprise a selected sequence of anisotropies and couplings to provide the regions of declining anisotropy interspersed with reset regions. This is further illustrated in FIG. 7.

As can be seen from FIG. 7, each region 3 of declining anisotropy gradient is divided from neighbouring regions 3 of declining anisotropy gradient by a reset region of increasing anisotropy gradient 5. As can also be seen from FIG. 7, the magnetic layers along the declining anisotropy gradient 3 are antiparallel coupled. This provides that a soliton in this region will propagate synchronously along the layers of the declining anisotropy gradient 3 under the influence of an applied field. In addition, the layers that span the reset region 5 are parallel coupled. This provides that a soliton in this region will propagate up increasing anisotropy gradient of the reset region under the influence of the same applied field. Although the propagation up the resent region is asynchronous, this a synchronicity is controlled by the finite length of the reset region. This will be discussed in greater detail below.

Thus a managed anisotropy gradient can be established in a sustainable way to enable a structure to contain a large length of decreasing anisotropy gradient region without limitations such as maximum or minimum anisotropy being reached. Thus, a uni-directional structure can be established which allows solitons that are achiral and sharp (and hence dense and energetically stable) to be propagated up a stack using a linear oscillating field.

Considering again the arrangement of FIG. 7, it can be seen that at each reset point 5, a layer is present which is parallel coupled to the layer beneath and which has a higher anisotropy than the layer beneath. At this point, the soliton follows the uni-directional propagation rules for parallel-coupling discussed above with reference to FIG. 6. That is, the soliton propagates asynchronously and therefore moves 2 layers in the same half-cycle of applied field and in the direction of increasing anisotropy, i.e. up the structure, pushing it past the sticking point of the reset. The structure and thus the soliton then reverts to anti-parallel coupled uni-directional behaviour until the next reset point is reached.

Accordingly, a layered structure having an indefinite number of layers can be made in which a soliton can be reliably propagated in a known and controlled manner under the influence of an applied field.

Having now established the principle of using a layered structure having magnetic layers with varying anisotropies to create a managed anisotropy gradient, it is appropriate to consider that the effect of the managed anisotropy gradient can also be achieved by approaches that vary a property other than the inherent anisotropy of the magnetic layers. Two addition approaches that have been shown to work are varying the inter-layer coupling strength between layers and varying the thickness of the magnetic layers. Each of these will be discussed in greater detail below. Thus, although these alternative approaches create an effect that behaves in the same way as the managed anisotropy gradient discussed above, it is believed to be more appropriate to refer to resulting net switching field. Resulting net switching field is the external field strength necessary to cause one disc of a soliton within a layered structure to switch magnetisation direction along its easy axis of anisotropy. A structure exhibiting a managed net switching field as described herein may be considered to operate in the manner of a ratchet where frustrations in order parameter of magentisation direction can be moved one position at a time through the structure having the managed net switching field profile as described herein. This is influenced by a number of factors as described below.

FIG. 8 illustrates a small section of a layered structure of magnetic layers to demonstrate the properties that can be altered to achieve this managed resulting net switching field. As shown in FIG. 8, a number of magnetic layers are provided. Each layer has an intrinsic anisotropy Hu. Each layer also has a thickness t. Between each pair of layers a coupling field strength J* operates. Varying each of these properties alters the resulting net switching field necessary to cause the magnetic moment of a given layer to switch directions along the easy axis of anisotropy of that layer. By controlling these properties within a layered structure as discussed both above and below, it is possible to create the field conditions for a structure that permits unidirectional propagation of a soliton or order parameter frustration within that layered structure.

Hc is the inherent coercivity of the material of the layer and is thus directly related to the anisotropy field strength Hu of the magnetic disk, which represents the externally applied field strength necessary to switch the magnetisation direction along the easy axis of anisotropy when no other field effects act upon the layer. The exact relationship between Hc and Hu depends upon the particular materials involved, although it is believed to be accurate to say that they increase and decrease together (i.e. that if Hu is increased then Hc also increases, although not necessarily in direct proportion). In a theoretical ideal material Hu and HC are equal. In most real materials, the ratio Hc/Hu≦1.

J* is the coupling field (which can be thought of as the coupling strength between adjacent magnetic layers or as the average interaction field in one magnetic layer due the presence of the neighbouring magnetic layer, in any case expressed as a magnetic field) and is unrelated to the anisotropy field strength Hu of the magnetic disk. The parameters that affect J* depend upon the dominant coupling mechanism between magnetic layers. Coupling mechanisms are discussed in more detail below. At this stage it is sufficient to consider that where dominant mechanism is direct or indirect exchange interaction (such as RKKY coupling) then J* is related to both the interface between the magnetic layer and any adjacent non-magnetic layer and the thickness of the magnetic layer itself. The impact of layer thickness is discussed more detail below. Where the dominant mechanism is magnetostatic coupling, J* is a function of the thickness of neighbouring magnetic and non-magnetic layers.

The effect that altering J* has is that where a given layer has different coupling strengths acting on different sides of the layer, there will be in the rest condition with a soliton straddling the given layer an unbalanced net field acting on the layer and thus the applied field strength required to switch the magnetisation direction along the easy axis of anisotropy will be higher for the direction with the stronger coupling field than the direction with the weaker coupling field. The following discussions relating to J* are based upon the magnitude of J*. Where adjacent layers are parallel-coupled J* will be positive and where adjacent layers are anti-parallel coupled, the actual value of J* will be negative.

t is the thickness of the layer and can determine the anisotropy field strength Hu of the magnetic disk. The mechanism by which the thickness alters the anisotropy varies according to the materials system in use. For materials having in-plane magnetisation, there is a tendency for the anisotropy strength to increase slightly with increased layer thickness. For materials having out-of-plane magnetisation created by ordered alloys in a multilayer structure (these are discussed in greater detail below) the anisotropy can be increased by increasing the number of repeat layers in the multilayer structure or by changing the relative thicknesses of the layers within the multilayer structure. This latter approach can have a profound impact on the anisotropy for a relatively small amount of sublayer thickness change.

Changing the thickness can also affect the coupling strength J* and thus cause the exchange interaction field J* to alternate high-low by changing the thickness instead of the anisotropy field being made to alternate high-low. As is discussed below, for exchange interaction coupled materials, increasing the layer thickness causes dilution of the interface coupling across a larger magnetic layer volume.

A further consideration for increasing layer thickness is that magnetostatic coupling strength increases with layer thickness. Thus, as exchange coupling weakens with increased layer thickness, the magnetostatic coupling becomes stronger. Thus layer thickness provides a balance to control the dominant coupling effect. In a system where magnetostatic coupling is dominant, varying the thickness has the opposite effect to that in an exchange interaction coupled system, i.e. increased thickness increased the coupling strength and decreased thickness weakens the coupling strength.

In many materials, an alteration in thickness will have some effect on both the anisotropy and the coupling. In some materials, the majority of the impact is on the anisotropy and in some materials the majority of the impact is on the coupling, and in some materials a balance of both occurs.

An additional parameter to consider is J, which is the property of the interface between a magnetic layer and a non-magnetic spacer layer (further discussion of spacer layers is provided below) in an indirect exchange coupling materials system (such as RKKY coupling). The consideration of this parameter provides greater explanation of some of the properties outlines above. J changes in an oscillatory fashion with the thickness of the non-magnetic layer. Its units are areal energy density. It is related to J* in that J* is J converted into an equivalent magnetic field. It means that if the entire magnetic layer acts as one (i.e. z-invariant in its response) then it is the equivalent magnetic field that would have to be applied to the entire magnetic layer to get the same response as is caused by the interface. Mathematically it is related to J by J*=J/(Ms t). It's reciprocal in t because J only acts on the interface atomic layer—as the magnetic layer gets thicker the effect of J is increasingly diluted across the full thickness of the magnetic layer and therefore looks like an increasingly weak magnetic field. If the magnetic layers are all the same thickness then the absolute difference between J and J* is, at least conceptually, of little concern since they're directly proportional. But if the magnetic layer thicknesses change, then J* and J are no longer equivalent terms.

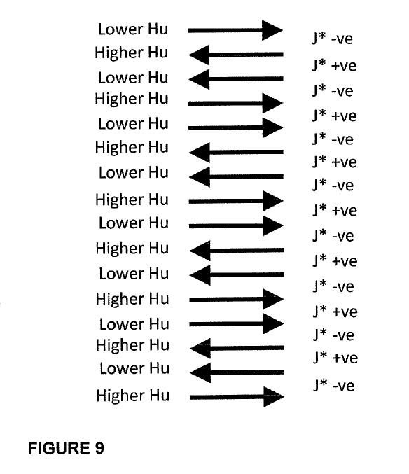

A simple form of such a structure where the anisotropy Hu is varied is illustrated in FIG. 9. In this case, the length of the downward anisotropy gradient is one layer pair and the length of the upward reset anisotropy gradient is one layer pair. Thus the structure alternates between parallel and anti-parallel coupling and higher anisotropy and lower anisotropy. In the illustrated example of FIG. 9, the propagation direction is up the page as each higher anisotropy layer is parallel coupled down the page to each respective lower anisotropy layer. An inversion of this sequence (e.g. exchanging lower and higher anisotropy or exchanging parallel and antiparallel coupling) has the effect of reversing the direction of uni-directionality.

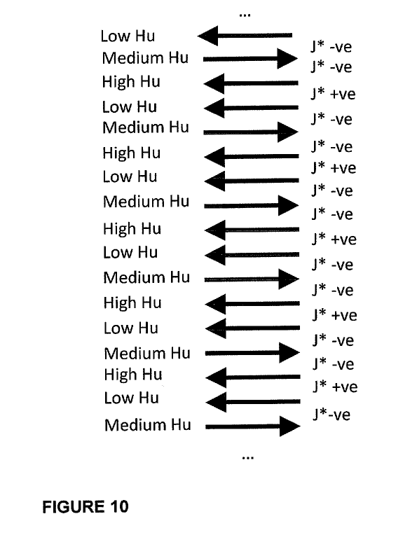

FIG. 10 illustrates another example structure based upon varying the anisotropy Hu in which each reducing gradient region has three layers, such that the structure has successive (starting at the bottom of the page) layers of high, medium and low anisotropy. The upward reset anisotropy gradient spans only two layers in the form of the jump from low to high anisotropy. The coupling between each high anisotropy layer and the upstream low anisotropy layer (i.e. the layer below as indicated on the page of FIG. 10) is parallel coupling (positive J*). The coupling between all other layer pairs is antiparallel coupling (negative J*).

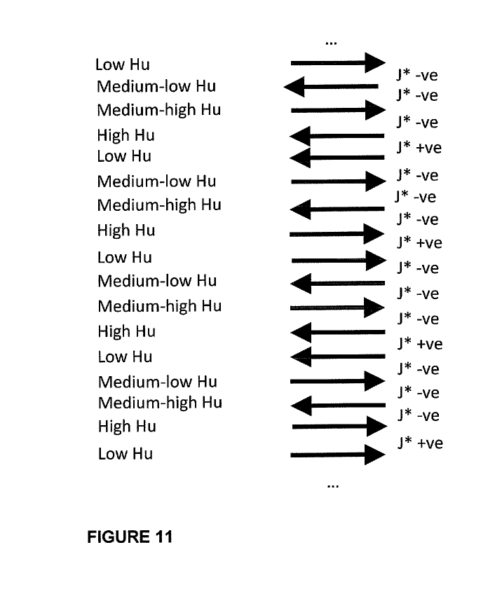

FIG. 11 illustrates another example structure in which each reducing gradient region has four layers, such that the structure has successive (starting at the bottom of the page) layers of high, medium-high, medium-low and low anisotropy. The upward reset anisotropy gradient spans only two layers in the form of the jump from low to high anisotropy. The coupling between each high anisotropy layer and the upstream low anisotropy layer (i.e. the layer below as indicated on the page of FIG. 11) is parallel coupling. The coupling between all other layer pairs is antiparallel coupling.

It will be appreciated that the number of antiparallel coupled layers making up the downslope of the managed anisotropy gradient can be extended to be as long as operational and materials considerations allow. Both operational and materials aspects of the implementation will be discussed in greater detail below.

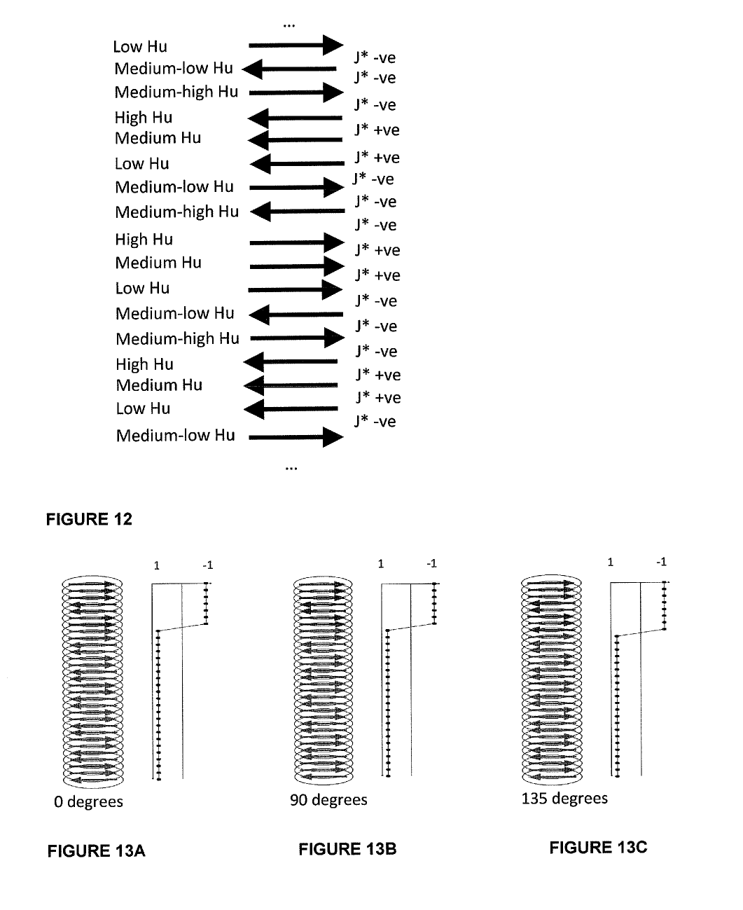

In addition, it is possible to extend the length of the reset region to include medium anisotropy layers instead of having the sharp jump from lowest to highest anisotropy in one layer. Such an arrangement is illustrated in FIG. 12. It should be noted however that the main effect of such an arrangement is likely to be a reduction in the maximum soliton density as a soliton will propagate the whole way along the reset (parallel-coupled, positive J*) region on a single half-cycle or pulse of applied field regardless of the number of layers in the reset region.

Thus it will now be understood how magnetic layers of varying anisotropies can be ordered and coupled in order to provide a field drive device having a managed profile of resulting net switching field so as to allow an indefinite number of layers to be present within the structure. Such a structure can hold and have propagated therethrough a number of solitons at any one time and such a plurality of solitons within the structure can be used to encode data in order that the structure can be used as a data store, or memory element.

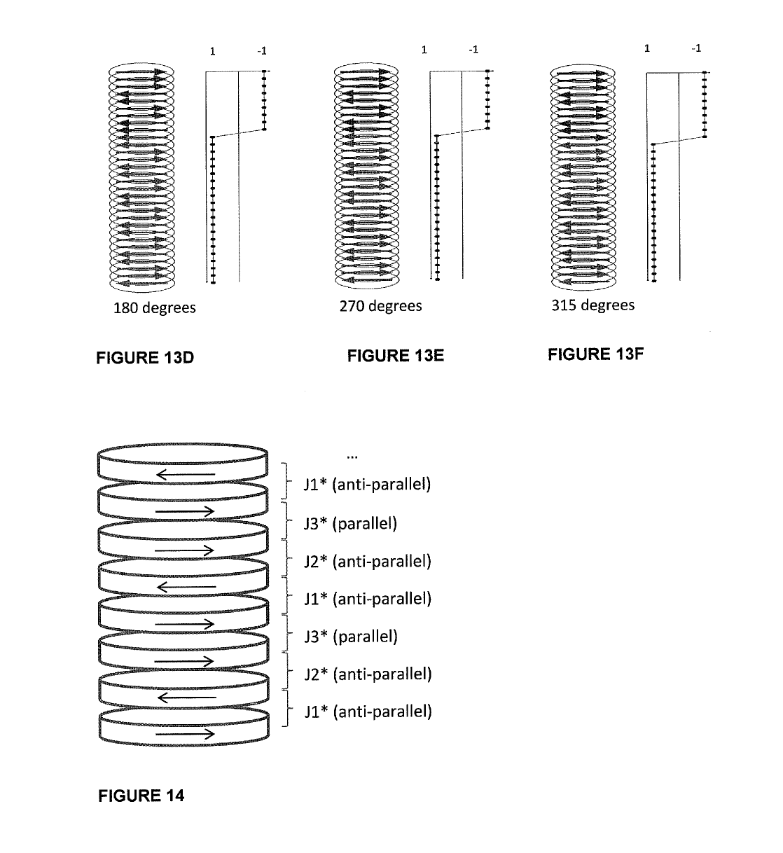

FIGS. 13A to 13F illustrates an example of soliton propagation along the structure of FIG. 9. The propagation is driven by a sinusoidal magnetic field acting along the length (i.e. height as shown on the page of FIG. 13) of the structure. The orientation of the stack in this example is such that the propagation direction is down the structure as seen on the page of FIG. 13. In order to facilitate understanding of the movement of the soliton along the structure, the illustration of the structure showing magnetisation directions is accompanied by a graphical representation of order parameter. The angle indicated is the phase angle of the cosine applied field where zero degrees is to the right in the figure. The uniaxial anisotropy easy axes are in the plane of the layers running left to right. At FIG. 13A the applied field is at a position of 0 degrees and the soliton is straddling an antiparallel coupled layer pair. At FIG. 13B the applied field is at a position of 90 degrees and at this stage the soliton has not moved. At FIG. 13C the applied field is at a position of 135 degrees and at this stage the soliton has moved one layer as the field strength at this angle is greater than the resulting net switching field to enable the soliton to move to straddle the next parallel coupled layer pair in the propagation direction. At FIG. 13D the applied field is at a position of 180 degrees (i.e. one half-cycle is completed) and the soliton has moved a further one layer to complete its journey up the reset region provided by the parallel-coupled pair and thus now rests at the next antiparallel-coupled pair. Thus in one half-cycle of applied field, the soliton has moved by two physical layers as it moved the whole way along the reset region in the one half-cycle.

At FIG. 13E the applied field is at a position of 270 degrees and at this stage the soliton has not moved further. At FIG. 13F the applied field is at a position of 315 degrees and at this stage the soliton has moved one layer as the field strength at this angle is greater than the resulting net switching field to enable the soliton to move to straddle the next parallel coupled layer pair in the propagation direction. Once this half-cycle is completed (i.e. the field returns to a position of 0 degrees), the soliton will have moved a further one layer to complete its journey up the reset region provided by the parallel-coupled pair and thus rest at the next antiparallel-coupled pair. Thus in the second half-cycle of applied field, the soliton again moves by two physical layers as it moved the whole way along the reset region in the one half-cycle.

A further discussion of the number of layers moved by a soliton per half cycle of applied field is presented below.

Thus it can be seen that a soliton can be reliably propagated along the propagation direction of a layered structure having a managed profile of resulting net switching field created by varying the anisotropy of successive layers.

Now, with reference to FIGS. 14 to 16, examples of providing a managed profile of resulting net switching field by varying the coupling strength will be discussed.

FIG. 14 illustrates a simple system in which the anisotropy Hu of each layer remains constant and in which the coupling strength J* is altered to provide the directionality for reliable soliton propagation. In this example, there are three different coupling strengths between the respective layers in the stack. J1* has negative sign and thus provides antiparallel coupling. J2* also has negative sign and thus provides antiparallel coupling. J3* has positive sign and thus provides parallel coupling. J1* has magnitude greater than J2*. By J1* having greater magnitude than J2*, then an applied field will move a soliton along the structure in the direction J1*→J2*→J3*→J1* etc.

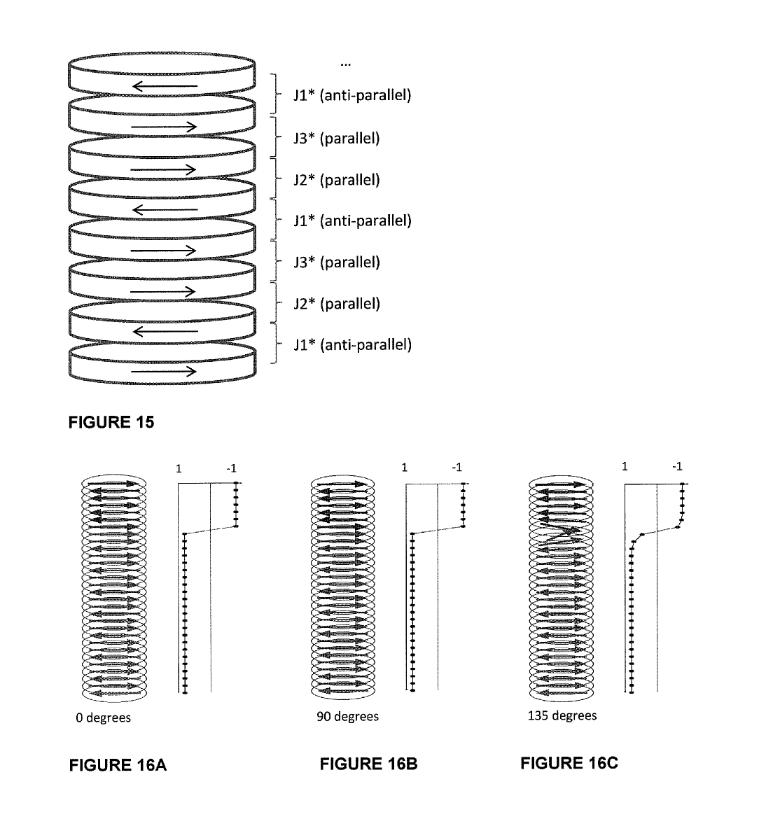

FIG. 15 illustrates another simple system in which the anisotropy Hu of each layer remains constant and in which the coupling strength J* is altered to provide the directionality for reliable soliton propagation. In this example, there are three different coupling strengths between the respective layers in the stack. J1* has negative sign and thus provides antiparallel coupling. J2* has positive sign and thus provides parallel coupling. J3* has positive sign and thus provides parallel coupling. J1* has magnitude greater than J2*. By J1* having greater magnitude than J2*, then an applied field will move a soliton along the structure in the direction J1*→J2*→J3*→J1* etc. In this example, because there is only one antiparallel coupled pair, a soliton would move all the way form one J1*/J2* pair to the next J1*/J2* pair on each half cycle or pulse of applied field.

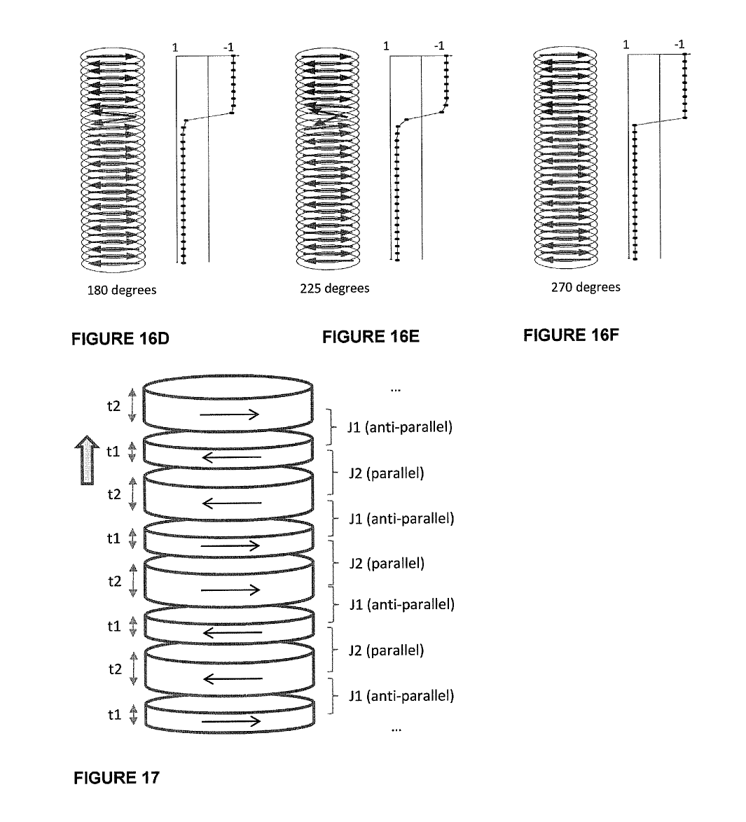

FIGS. 16a to 16e illustrate an example of soliton propagation along the stack of FIG. 14. The propagation is driven by a sinusoidal magnetic field acting along the length (i.e. height as shown on the page of FIG. 16) of the structure. The orientation of the stack in this example is such that the propagation direction is down the structure as seen on the page of FIG. 16. In order to facilitate understanding of the movement of the soliton along the structure, the illustration of the structure showing magnetisation directions is accompanied by a graphical representation of order parameter. The angle indicated is the phase angle of the cosine applied field where zero degrees is to the right in the figure. The uniaxial anisotropy easy axes are in the plane of the layers running left to right. At FIG. 16A the applied field is at a position of 0 degrees and the soliton is straddling an antiparallel coupled layer pair immediately preceding in the propagation direction a parallel coupled layer pair. At FIG. 16B the applied field is at a position of 90 degrees and at this stage the soliton has not moved. At FIG. 16C the applied field is at a position of 135 degrees and at this stage the soliton has started to move as the field strength at this angle is starting to exceed the resulting net switching field to enable the soliton to move to straddle the next parallel coupled layer pair in the propagation direction. At FIG. 16D the applied field is at a position of 180 degrees (i.e. one half-cycle is completed) and the soliton has moved by two layers (i.e. the whole length of the rest region at the parallel-coupled pair) and thus now rests at the next antiparallel-coupled pair. Thus in one half-cycle of applied field, the soliton has moved by two physical layers as it moved the whole way along the reset region in the one half-cycle.

At FIG. 16E the applied field is at a position of 225 degrees and at this stage the soliton is starting to move but is still at the same parallel-coupled layer pair. At FIG. 16F the applied field is at a position of 270 degrees and at this stage the soliton has moved one layer as the field strength at this angle is greater than the resulting net switching field to enable the soliton to move to straddle the next antiparallel coupled layer pair in the propagation direction. Once this half-cycle is completed (i.e. the field returns to a position of 0 degrees), the soliton will have moved a total of one layer as this half-cycle propagation corresponded to movement from antiparallel couple pair to another antiparallel coupled pair.

A further discussion of the number of layers moved by a soliton per half cycle of applied field is presented below. As can be seen from these figures, a soliton may behave as a composite body under propagation and thus doesn't necessarily reach a distinct position at every point within the cycle.

Thus it can be seen that a soliton can be reliably propagated along the propagation direction of a layered structure having a managed profile of resulting net switching field created by varying the coupling strength of successive layers.

Now, with reference to FIG. 17, examples of providing a managed profile of resulting net switching field by varying the magnetic layer thickness will be discussed.

In FIG. 17, a structure functionally very similar to that of FIG. 9 is shown in that the structure consists of alternating thin and thick magnetic layers having alternating parallel and antiparallel coupling. The antiparallel coupling occurs (when considered in the propagation direction) between the each thin layer and the next thick layer and the parallel coupling occurs (when considered in the propagation direction) between the each thick layer and the next thin layer. In this example, it is assumed that the alteration of the thickness has negligible effect on the anisotropy of the layers and that the main effect is the dilution of J over the increased or decreased thickness and thus altering the coupling J*. Testing has confirmed that a t1, t2 system of the type depicted in FIG. 7 where there is some variation of Hu1 and Hu2 due to the thickness changes leads to an operational structure.

Thus there have now been described a number of physical arrangements for creating a layered structure of successive magnetic layers in which the magnitude of the layer anisotropy, layer thickness or inter-layer coupling is controlled to provide a propagation direction along the structure and along which a soliton can be reliably and synchronously propagated under the influence of an applied field acting along the propagation direction. In addition, the techniques described above can be combined within a single structure. Thus a device may use a combination of varied anisotropy and varied thickness, a combination of varied anisotropy and varied coupling strength, a combination or varied thickness and varied coupling strength, or a combination of all three.

Two further considerations to be looked at are the methods by which data can be encoded onto the structure and the minimum soliton spacing (which affects the maximum data density within the structure).

The minimum soliton spacing is a spacing that enables the solitons to co-exist near one-another without a danger of the solitons either combining or repulsing one-another. Combining of solitons would result in data loss and solitons repulsing one another could affect the reliability and synchronicity of propagation and thus could result in a soliton failing to propagate when driven by the external field or propagating without being driven by the external field. In practice, it is seen that a minimum spacing (period) of three logical layers is required. The value of three logical layers arises as two logical layers are inherently required to hold the soliton and the third layer provides space for the solitons to move slightly different points on the half-cycle of applied field without collision. A distinction is made herein between logical layers and physical layers as all physical layers of the reset region count as one logical layer as a soliton moves the whole way along the reset region on a single half-cycle or pulse of applied field.

Using the example of FIG. 9, as is seen above from the propagation flow of FIG. 13, the parallel-coupled physical layer pair of the reset region count as 1 logical layer and as there is only one antiparallel-coupled physical layer pair between the reset region, it takes 2 physical layers to provide one logical layer and so the minimum soliton spacing is 6 physical layers. The same would apply to the example of FIG. 17. The example of FIG. 15 used three physical layers to provide one logical layer and so the minimum soliton spacing for this example would be 9 physical layers.

Using the Example of FIG. 10, the densest soliton population available provides 2 solitons over 9 physical layers, giving a equivalence of three logical layers=4½ physical layers. This has the effect that each 3 logical layer soliton space covers only a single parallel-coupled layer pair. The same spacing would apply to the example of FIG. 14.

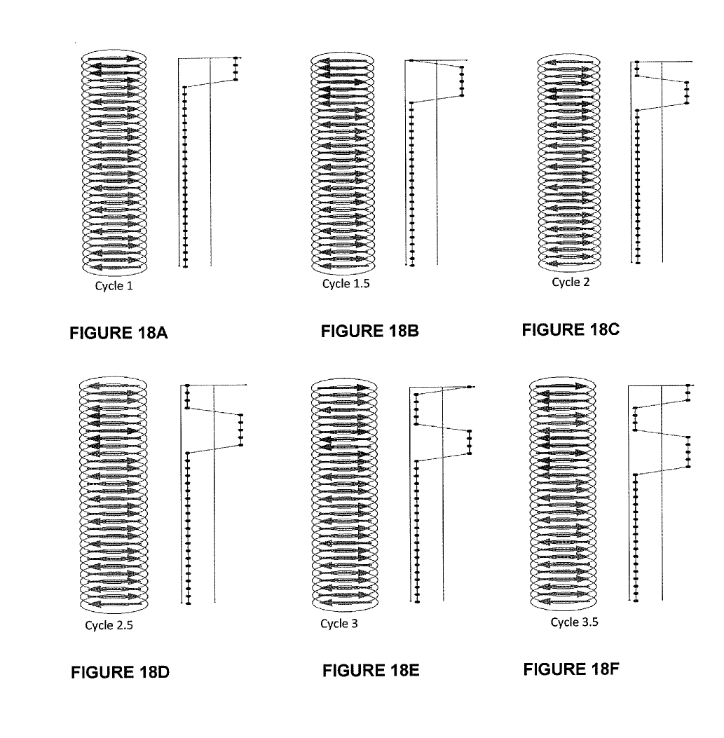

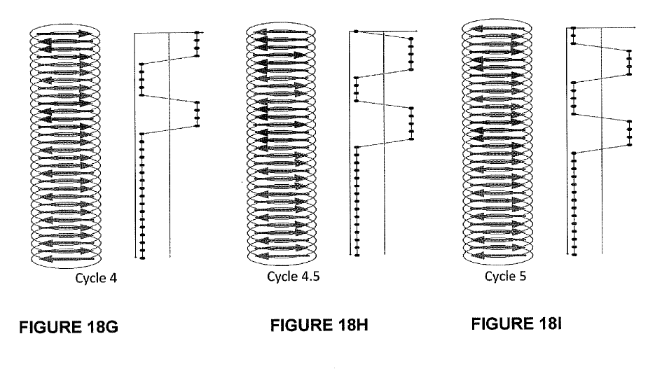

An example of soliton propagation with high density soliton presence is shown in FIGS. 18A to 18I. This example uses a structure of two antiparallel coupled pairs between each parallel coupled pair, and thus could be provided by, for example, the arrangements of FIG. 10 or 14 above. In this example, a new soliton is injected into the structure every 1.5 cycles. The propagation direction of this example is down the page of the Figures.

FIG. 18A shows that at the end of applied field cycle 1, a single soliton is present and is three logical layers down the structure. At the end of cycle 1.5 (FIG. 18B), the original soliton has moved one logical layer down the structure and a second soliton has been introduced at the first logical layer. At the end of cycle 2 (FIG. 18C), the original soliton has moved a further logical layer through the structure and the second soliton is now at the second logical layer. It will be noted as between cycles 1.5 (FIG. 18B) and 2 (FIG. 18C) that the spacing between the first and second solitons alters by one physical layer. This is due to the impact of the two physical layers of the parallel-coupled layer pair constituting a single logical layer for the purposes of soliton propagation. This effect will be observed in relation to the soliton spacings between all solitons at different points in the propagation.

The propagation continues to cycle 2.5 (FIG. 18D), where the solitons are each one logical layer further on through the structure, such that the second soliton is now three logical layers down. At the end of cycle 3 (FIG. 18E), the first two solitons again are moved one logical layer further through the structure and a third soliton is injected three logical layers behind the second. At the end of cycle 3.5 (FIG. 18F), all three solitons are a further logical layer down the structure. At the end of cycle 4 (FIG. 18G), the solitons are again all moved by one logical layer and the third soliton is now three logical layers down the structure. At the end of cycle 4.5 (FIG. 18H), the solitons are again all moved by a further logical layer and a fourth soliton is injected three logical layers behind the third. At the end of cycle 5, a further logical layer of propagation has been applied to all solitons.

Thus the propagation process as well as the variance in physical layer separations during different propagation cycles due to the impact of the parallel-couple layer pairs can be seen,

If one considers a structure having eight antiparallel-coupled layer pairs between each reset region and the reset region comprises a single parallel-coupled pair, then the three logical layers become, on average over the structure, 3⅓ physical layers. The fractional layer again appears because some up to three solitons will fit on the nine logical layer pairs (which are made up of 10 physical layers) and thus the maximum soliton density to give a three logical layer spacing is 10/3 layers per soliton on average.

Thus it can be seen that by extending the length of each downslope region of the managed anisotropy gradient while keeping a minimum reset region length, the number of layers will asymptotically approach three physical layers per soliton. The selection of the number of layers in the downslope region can depend on a number of factors, including materials and fabrication considerations and thus it may be appropriate in some implementations to accept a maximum density of 9 physical layers, 6 physical layers, 4 physical layers or just under 4 physical layers rather than extending the downslope length to further reduce the maximum soliton density. It should be noted that where the structure has a number of layers which is not an exact multiple of the maximum soliton density, the structure is still operable and the maximum number of solitons will be the integer part of the total number of layers divided by the maximum soliton density. Thus if the structure has a number of layers that is an exact multiple of the maximum soliton density, then the result of that same calculation will be an integer value.

Within each stack, data can be encoded according to one of a number of possible schemes.

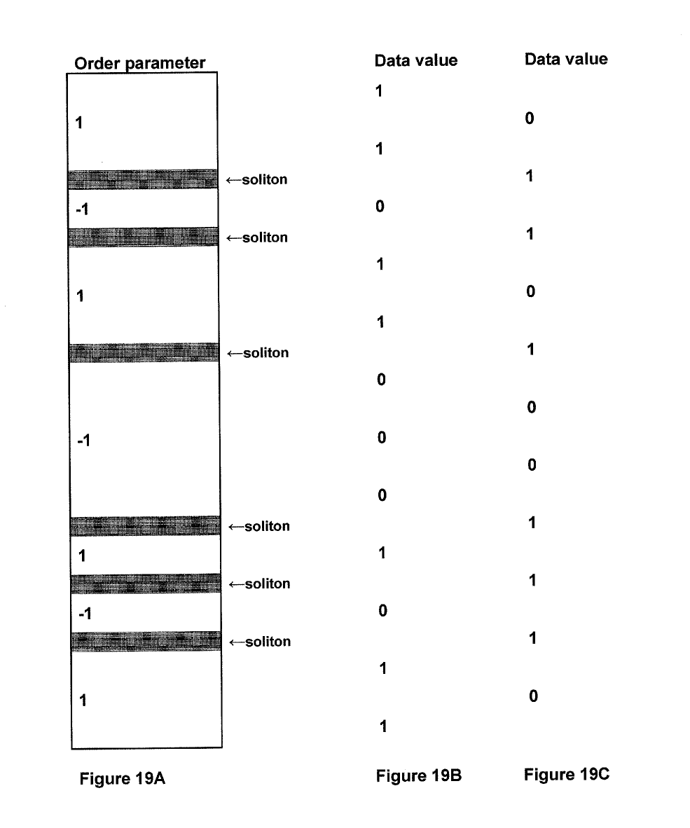

Two specific example encoding schemes are illustrated with reference to FIGS. 19A, 19B and 19C. The first scheme uses the order parameter to represent data values. As such all regions having a first order parameter are treated as carrying a data value of 1 and all regions having the opposite data parameter are treated as carrying a data value of 0. Each predetermined number of logical layers having the given order parameter corresponds to a single data bit. The second scheme uses the presence or absence of a soliton to represent data values. As such each predetermined possible soliton position can represent either a data value of 1 or 0 depending on whether a soliton is present or not. These encoding schemes are illustrated in FIGS. 19A, 19B and 19C.

FIG. 19A shows schematically a layered structure in which a number of regions of different order parameter (value 1 or −1) are defined by the presence of a number of solitons.

FIG. 19B shows the data content as present according to the first encoding scheme, where the value of the order parameter encodes the data. In this example an order parameter value of 1 corresponds to a data value of 1 and an order parameter value of −1 corresponds to a data value of 0, although the reverse encoding (1→0, −1→0) is also possible. Thus, as is seen, the data carried by the stack according to this encoding scheme provides a data value of 1 for every inter-possible-soliton-position region that carries an order parameter value of 1 and a data value of 0 for every inter-possible-soliton-position region that carries an order parameter value of −1.

FIG. 19C shows the data content as present according to the second encoding scheme, where the presence or absence of a soliton encodes the data. In this example a soliton presence at a possible-soliton-position corresponds to a data value of 1 and soliton absence at a possible-soliton-position corresponds to a data value of −1, although the reverse encoding (soliton present→0, soliton absent→0) is also possible. Thus, as is seen, the data carried by the stack according to this encoding scheme provides a data value of 1 for every possible-soliton-position that carries a soliton and a data value of 0 for every possible-soliton-position that does not carry a soliton.

Another suitable encoding scheme would be to use an exact copy of existing hard disc coding schemes. Thus a 1 to −1 order parameter transition in the stack can be taken as equivalent to head to head in hard disk encoding and a −1 to 1 order parameter transition in the stack can be taken as equivalent to tail to tail in hard disk encoding (or vice versa). By taking such an encoding approach, existing hard disk drive turbo codes can be recycled for use in a solid state magnetic data store.

Another suitable example of an encoding scheme is one utilising phase shift keying. This example has application in a situation where neighbouring stacks of a device are close enough that interactions between adjacent stacks are a possible source of erroneous behaviour. In this approach, the mark space ratio is controlled and the overall structure of soliton presence or absence between neighbouring stacks is approximately controlled. In one specific example, the encoding used could utilise a soliton at every fourth position (position 1 of every group of four positions) and an encode data values by inserting a soliton at position 2 for data value one or position 3 for the data value zero (or vice versa). In this example, position 4 would always be empty of a soliton Such an encoding example provides that half of the possible soliton positions have a soliton present and thus smoothes the presence or absence of solitons in the event of a large number of sequential data bits of the same value.

Thus there have now been described a number of possible field drive data storage structures utilising soliton holding layered structures and data encoding schemes by which solitons within the layered structure can encode data for storage and later retrieval.

In the following, a description will be provided of examples illustrating how the layered structures for a propagation field driven device can be implemented to have the couplings, thicknesses and anisotropies set out above.

Although some examples vary from the following structure, the basic structural elements which serve to illustrate the present disclosure are that the various magnetic layers discussed above are separated by a non-magnetic spacer layer. As mentioned above, each layer has an easy axis of anisotropy along which the magnetisation direction of the layer will lie. In general, the easy axes of anisotropy of successive layers are substantially parallel. This, in combination with the non-magnetic spacers, facilitates the inter-layer coupling of the magnetic layers to have either parallel or antiparallel alignment. As is made clear in the following description, the coupling direction between layers and the anisotropy of each layer (i.e. the tendency for the magnetisation direction of each layer to resist reversal) can be controlled by the materials and dimensions of the various layers.

In some examples, the magnetic layers are configured such that the dominant effect that controls the inter-layer coupling is dipolar field coupling (magnetostatic interactions) and in other examples the magnetic layers are configured such that the dominant effect that controls the inter-layer coupling is RKKY (Ruderman-Kittel-Kasuya-Yosida) exchange interactions. In general, and as mentioned above, the main factor in controlling which coupling phenomenon is dominant is the dimensions of the disks as RKKY coupling tends to be strongest for small spacer thickness and dipolar coupling tends to be strongest for large magnetic layer thickness. Thus, where it is appropriate to use a fabrication technique offering minimum layer thickness in order to improve volumetric density of soliton and thus data storage, a fabrication based on RKKY coupling may be most appropriate. Where RKKY suitable materials are not deployable or not available and/or where volumetric density is of lower concern, then fabrication based upon dipolar coupling may be appropriate.

RKKY coupling uses an RKKY compatible material as a spacer layer between magnetic discs. The coupling strength across a given thickness of a given spacer layer material can vary greatly depending upon the exact combination of magnetic and spacer materials and upon the fabrication techniques used to create the structure. Thus although some dimensional examples are given herein, the skilled person will understand that a given implementation may require verification and adjustment in order to achieve required anisotropy and coupling strengths. For example, a dimensional and materials combination may be determined by calculation, after which that combination is fabricated and tested to determine the actual strengths such that an iterative process of adjustment of a dimension or material may be made in order to create a further test sample. Such an iterative process to check actual properties against calculated properties may thus form a part of the design and fabrication process for any given implementation.

The layered structure may typically be considered as a stack of magnetic elements (interspersed with non-magnetic spacers as appropriate). As will be discussed further below, a number of manufacturing techniques may be applied to create such a structure. Each layer may be circular or approximately circular (non-circular shapes such as ellipses can be used to provide shape anisotropy to govern easy axis direction) such that each structure may take the form of a cylindrical or almost cylindrical stack of discs. As will be appreciated, the anisotropy of each layer is related to the strength of magnetic field required to cause the magnetisation direction to change from one direction along the easy axis of anisotropy to the other direction along that axis.

The easy axis of anisotropy in each magnetic layer can be provided in a number of ways. Suitable examples include shape anisotropy, magnetocrystalline anisotropy or stress anisotropy. Stress anisotropy is where placing a material under tension or compression can alter the magnetic properties of the material. For example if a stack of layers having no defined easy axis of anisotropy has a compressive force applied along the length of one side of the stack, then easy axes of anisotropy would be expected to appear in substantially the same direction in each layer.

In the example of shape anisotropy, the stack of disks would be made to have a non-circular cross section (typically an ellipse). Using an ellipse shape will generate a uniaxial anisotropy with easy axis directed along the long axis of the ellipse. The strength of the anisotropy field is a function of the thickness of the magnetic layers and the extent of the ellipticity (i.e. how far removed the disk is from a circle). Examples of suitable methods of creating a structure using such an approach is epitaxial growth and other thin film deposition methods such as chemical or physical deposition techniques including electro deposition and physical vapour deposition.

Magnetocrystalline anisotropy includes two sub-options for implementation. The first is to choose a material having magnetic layers which possesses an intrinsic anisotropy. Examples of suitable methods of creating a structure using such an approach is epitaxial growth and other thin film deposition methods such as chemical or physical deposition techniques including electro deposition and physical vapour deposition. The second option is to impose anisotropy on the material by growing it in the presence of a strong magnetic field or at an oblique deposition angle. These approaches are described in the context of sputter deposition (a form of physical vapour deposition) by Gentils, A, Chapman, J N, Xiong, G, et al, Variation of domain-wall structures and magnetization ripple spectra in permalloy films with controlled uniaxial anisotropy, J APPL PHYS, 2005, Vol: 98, ISSN: 0021-8979 (deposition in the presence of a strong magnetic field) and U.S. Pat. No. 6,818,961 (deposition from an oblique deposition angle).

As magnetocrystalline anisotropy depends on the material properties of the materials making up the layers whereas shape anisotropy depends on the overall dimension of the layer, it is possible that a given magnetic layer could have its overall anisotropy controlled by a combination of magnetocrystalline and shape anisotropy effects.

In order to control the coupling direction (i.e. parallel or antiparallel) between the layers, a number of options are available. In an example where the magnetic layers can be separated by metallic non-magnetic spacer layers (e.g. ruthenium, copper or chromium) to provide RKKY coupling as the dominant coupling force between magnetic layers, one approach for controlling the coupling direction is to select the thickness of the spacer between the antiparallel coupled layer pairs to correspond to an “antiferromagnetic peak” of the oscillatory RKKY coupling decay curve and to select the spacer thickness for the parallel-coupled layer pairs to correspond to a “ferromagnetic peak” of the oscillatory RKKY coupling decay curve. Further information relating to the oscillatory decay curve for RKKY coupling is given in RKKY Ultrathin Magnetic Structures 2—ISBN-3-540-57687-8/ISBN-0-387-57687-8, Editors J. A. C. Bland and B. Heinrich. Chapter 2: Magnetic coupling and magnetoresistance.

Another approach for an RKKY coupled structure is to use for the antiparallel-coupled layer pairs, as above, a metallic non-magnetic spacer (e.g. Ru, Cu or Cr) with a thickness selected to correspond to an “antiferromagnetic peak” of the oscillatory RKKY coupling decay curve, and to use for the parallel-coupled layer pairs an insulator (or semiconductor e.g. Si or Ge) for the spacer as such materials lead to a parallel coupling. Further information relating to the RKKY behaviour of insulators and semiconductors is given in RKKY Ultrathin Magnetic Structures 2—ISBN-3-540-57687-8/ISBN-0-387-57687-8, Editors J. A. C. Bland and B. Heinrich. Chapter 2: Magneticcoupling and magnetoresistance.

Another approach is to place the two layers that are to be parallel-coupled in direct contact with each other, allowing direct exchange coupling (as opposed to the indirect exchange coupling of RKKY). In this approach, the magnetic layer thickness will be greater than the domain wall width of that material so that the strength of the direct exchange coupling does not cause the two layers to lock together magnetically and behave as a single magnetic layer. Further consideration of this issue of layer thickness is presented in US2010/0062286 A1 (Suess, D.).

Where a structure is constructed to use dipolar coupling as the dominant coupling mechanism, the parallel coupling is typically achieved by way of direct exchange coupling as mentioned above. The antiparallel coupling is typically achieved by using a non-magnetic spacer layer. The paper by Carignan et al, Journal of Applied Physics 102, 023905 (2007); doi:10.1063/1.2756522 provides some information relating to appropriate materials choices and the considerations for determining the dipolar interaction.

In order to control the anisotropies of the respective magnetic layers, a number of options are available. For example, it is possible to select a different material for each magnetic disc according to the required anisotropy. Thus, in the example of a structure having successive high, medium and low anisotropy layers, the high anisotropy layer could be Co, the medium anisotropy layer could be CoFe and the low anisotropy layer could be permalloy or CoFeB.

Another approach, which could be used alone or mixed with the different materials approach above, is to alter the later thicknesses of the magnetic layers. In general, thicker layers tend to have higher anisotropies and so a low anisotropy layer could be thinner than a medium anisotropy layer which in turn is thinner than a high anisotropy layer. This approach is may be particularly appropriate if the easy axis of anisotropy of each magnetic layer is caused by shape anisotropy through use of an elliptical shape of each magnetic layer.

Another approach is to use perpendicularly magnetised materials made from interdigitated layers of, for example, Co—Pt, Co—Pd or Co—Ni. For such materials, the anisotropy is related to the number of repeat layers and thus the number of repeat layers making up each magnetic layer of the structure can be tailored according to the desired anisotropy. The anisotropy is also related to the relative thickness of the magnetic and non-magnetic repeat layers and thus the thickness of the CO layer, for example, can be reduced or increased in order to increase or reduce the anisotropy. The anisotropy is also related to the non-magnetic material in the ordered alloy and thus the anisotropy can be reduced by, for example, substituting Co—Pd for Co—Pt. Examples of considerations relevant to changing the anisotropy of a Co—Pd material by changing the cobalt layer thickness are given in: P. F. Carcia, A. D. Meinhaldt, A. Suna, Applied Physics Letter 47, 178 (1985). Examples of materials based upon Co—Pd and Co—Pd—Co—Ni layers are given in: Hellwig et al, Applied Physics Letter 95, 232505 (2009). Examples of considerations relevant to varying anisotropy by changing the cobalt layer thickness are given in: Lin et al, Journal of Magnetism and Magnetic Materials 93, 194 (1991). Examples of CoFeB (alloy) with MgO interface are given in: Ikeda et al, Nature Materials 9, 721 (2010). This last example of a perpendicularly magnetised material uses materials that have already been well developed for in-plane use. In addition, this material provides lower anisotropy than Co—Pd or Co—Pt and thus could provide a suitable material choice for the lowest anisotropy layers of a given structure. Also, with reference to the discussion of reading and writing interfaces below, the MgO interface could be used to form reading and/or writing elements and a different interface could be substituted for use within the body of the layered structure. Examples of the use of L1₀ ordered (Co,Fe)—Pt alloys as perpendicular materials for data storage are given in: IEEE Transactions on Magnetics 44, 2573 (2008).

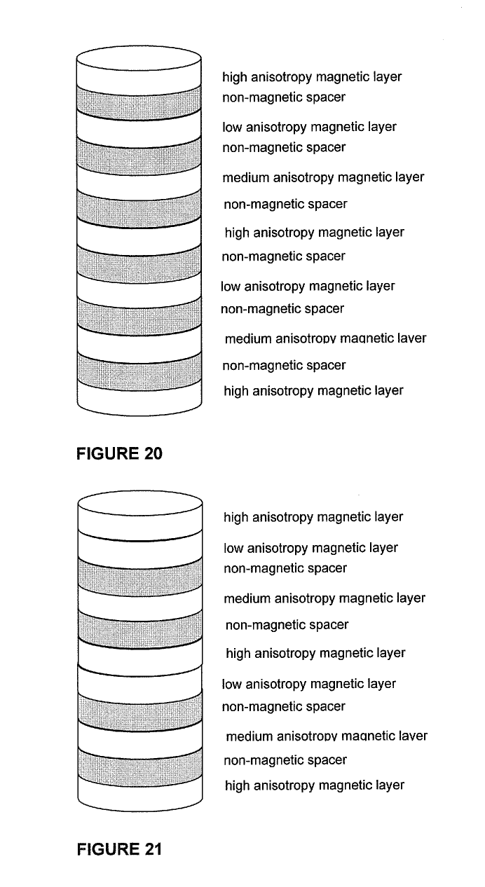

FIGS. 20 and 21 show two different examples of a layered structure to implement the arrangements shown logically with respect to FIG. 10. It will be appreciated that implementing the arrangements of FIG. 9, 11 or 12, or other arrangements with different numbers of layers in the downslope and reset regions of the managed profile of resulting net switching field can be achieved by altering the number of layers provided in each part of the layered structure.

In FIG. 20, each magnetic layer is separated from neighbouring magnetic layers by a non-magnetic spacer layer. Each magnetic layer has a high, medium or low anisotropy provided by one of the various methods described above and the coupling direction between the various magnetic layers is controlled by one of the various methods described above. This approach uses RKKY coupling as the dominant coupling effect as this enables the provision of both parallel aligned and antiparallel aligned couplings using spacer layers.

In FIG. 21, the medium anisotropy layer is separated from both the neighbouring low anisotropy layer and neighbouring high anisotropy layer by a non-magnetic spacer layer. The low and high anisotropy layers (the parallel-coupled layer pair) are however directly adjacent to provide for direct exchange coupling between those layers. This approach could use either RKKY coupling or dipolar coupling as the dominant coupling effect across the spacer layers as both techniques provide for antiparallel coupling across a spacer layer and the coupling for the non-spaced layers would be direct exchange coupling as mentioned above.

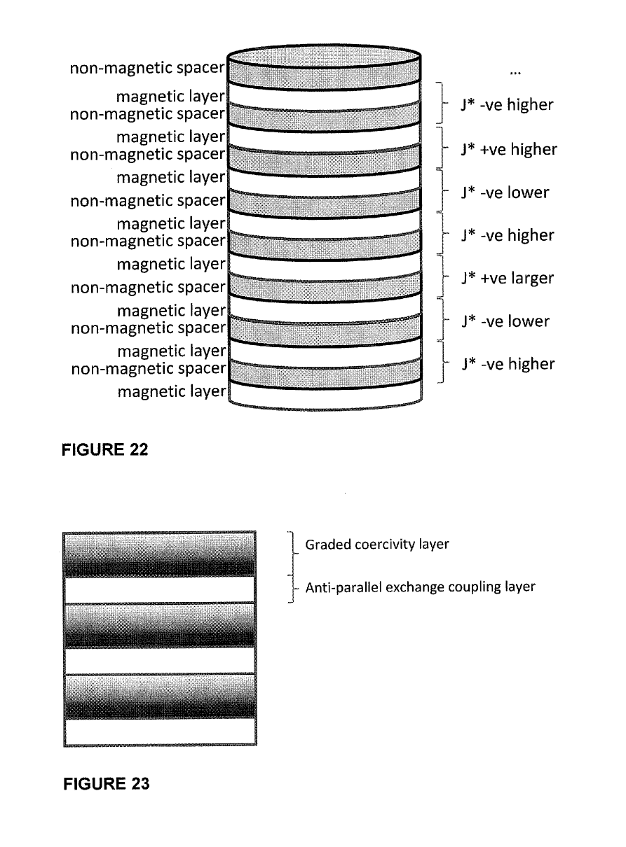

In FIG. 22 there is shown an example of a further layered structure, this time to implement the arrangement of FIG. 14. In this example, all magnetic discs have the same anisotropy Hu and the coupling strengths are varied. The positive J* indicated parallel coupling and the negative J* indicated antiparallel coupling. It is not necessary for the coupling strength for the J*+ve higher and J*−ve higher couplings to of the same magnitude. The functionality is provided by the magnitude of J*−ve lower being smaller than that of either of the higher values. As was discussed above, it is also possible to use J*+ve lower in place of J*−ve lower.

FIG. 23 shows a further example of a layered structure, this time to implement the arrangements shown logically with respect to FIG. 9. In this example, graded anisotropy layers are provided (in the Figure the highest anisotropy is at the top of the graded layer and the lowest anisotropy is at the bottom of the layer), separated by antiparallel exchange coupling layers. This provides that within the graded anisotropy layer there is effectively provided the reset region of the managed anisotropy gradient and the antiparallel coupled link between adjacent graded anisotropy layers provides the downslope of the managed anisotropy layer. The graded anisotropy layer may typically be provided using an exchange spring media approach such as one of those suggested by Victora or Suess as mentioned above. Further, some experimental examples of graded coercivity of Co/Pd materials by changing the Co thickness throughout the repeat layers are given in: Kirby et al, Physical Review B 81, 100405(R) 2010, and some experimental examples of graded coercivity FePtCu films are given in: Bonanni et al, Applied Physics Letter 97, 202501 (2010).

The use of exchange spring media in the form of a graded anisotropy layer is likely to result in a reduced data storage density compared to the thin film techniques discussed above as the graded anisotropy layer will have a size as thick as or thicker than one domain wall width in that material (usually around 10-50 nm). Thus the repeat period will end up being greater than if distinct layers with explicit ferromagnetic coupling between them were to be used. However despite this reduction in density compared to other approaches, this particular approach may be appropriate for a manufacture based upon electrodeposition into templating pores. Such a templated deposition approach provides a relatively fast and inexpensive approach for formation of very high aspect ratio structures. However, when using this construction technique, it is expected that the inter-layer interface quality within the created structure would not be clean enough to reliably use RKKY coupling, such that dipolar coupling (which is always anti-parallel between layers of in-plane magnetised material) would typically be the dominant coupling effect. Since the layer thickness of a dipolar coupled system would be expected to be of the order of tens of nm per layer, there would be space to use a graded anisotropy layer. Under some circumstances, this in fact might be easier to fabricate under electrodeposition than two distinct ferromagnetic materials of different anisotropy. Thus, in the example of fabrication using electrodeposition into templating pores (regardless of whether the magnetic layers are graded anisotropy layers or distinct anisotropy layers), the anti-parallel exchange coupling layer separating the magnetic layers would not be an RKKY coupler like Ruthenium, but rather any non-magnetic spacer whose only job is to keep the layers apart, allowing them to couple anti-parallel through dipolar interactions. An example of a suitable spacer material is Cu. Some general background on the technology of creating electrodeposited nanowires can be found in Carignan et al, Journal of Applied Physics 102, 023905 (2007); doi:10.1063/1.2756522.

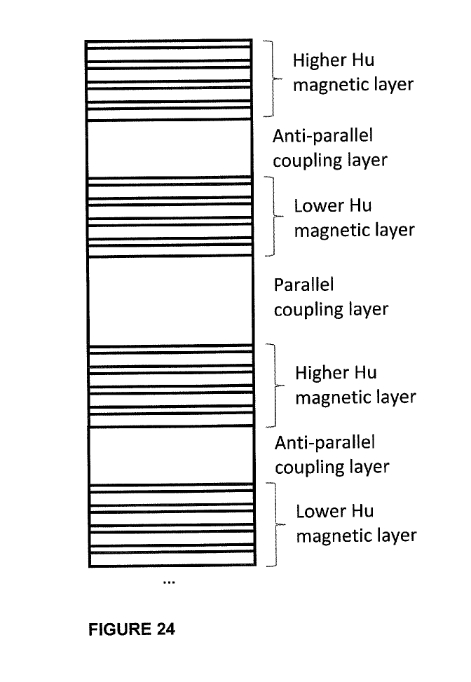

FIG. 24 shows a further example of a layered structure to implement the arrangements shown logically with respect to FIG. 9. In this example, the magnetic layers are perpendicularly magnetised materials. Each magnetic layer is itself made up of a multilayer structure. The higher anisotropy layer could be CoPd and the low anisotropy layer could be CoPd with a different thickness of the Co layers in the CoPd ordered alloy layer to alter the anisotropy.

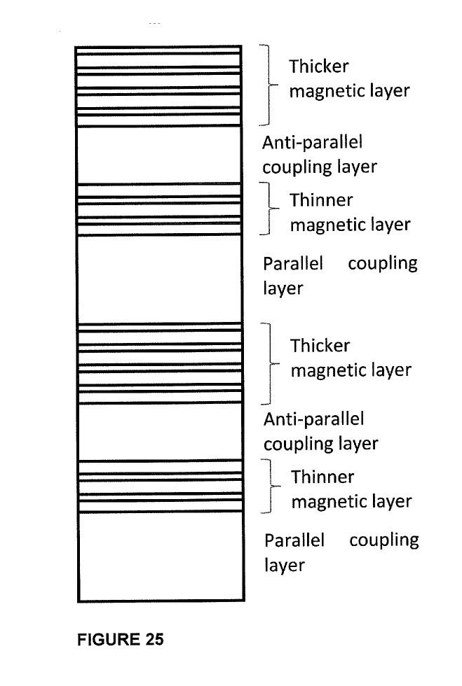

FIG. 25 shows an example of a layered structure to implement the arrangements shown logically with respect to FIG. 17. In this example, the magnetic layers are perpendicularly magnetised materials. Each magnetic layer is itself made up of a multilayer structure. The thick magnetic layer could be CoPd and the thin layer could be CoPd with a different number of repeat layers in the CoPd ordered alloy to alter the thicknesses of the magnetic layers.

Thus there have been described a number of approaches and techniques for producing a field driven magnetic thin film device capable of maintaining therein and having propagated therethrough one or more stable transitions in an order parameter describing the alignment of magnetic moments within the layers of the structure. Such devices can be used to store data encoded into the order parameter transition sequences or presences.

As noted above, in all construction approaches, there will be a relationship between the relative strength of the coupling field (which can be thought of as the coupling strength between adjacent magnetic layers or as the average interaction field in one magnetic layer due the presence of the neighbouring magnetic layer, in any case expressed as a magnetic field) J* (or the coupling areal energy density J) and the anisotropy field (anisotropy field strength of each magnetic disk) Hu. Again, discussions relating to J* are based upon the magnitude of J*. Where adjacent layers are parallel-coupled J* will be positive and where adjacent layers are anti-parallel coupled, the actual value of J* will be negative.

In general, a large J* may be appropriate as large J* leads to a high nucleation field strength. By having a high nucleation field strength the operating margin for the applied field strength for propagation is increased, as the propagation field in most cases needs to be at a level below that which will cause spontaneous soliton nucleation at an uncontrolled position in the structure. However, if the value of J* becomes too large, the soliton will stop being sharp or abrupt and will spread itself across several layers. This will have the effect of reducing the energy barrier for propagation ΔEp (hence reducing data stability) and/or of reducing the minimum soliton spacing that can store data stably for a given anisotropy. Modelling of the properties suggests that soliton broadening begins when J*˜Hu/2. Therefore in some implementations it may be appropriate to control the relationship between J* and Hu such that want J* is around Hu/2 or slightly less.

In general, a large Hu may be appropriate since the energy barrier separating stable positions of the soliton scales linearly with Hu. Increased Hu therefore leads to increased data stability and/or the ability to reduce the volume of each data storage element without the risk of thermal instability setting in. However, where solitons need to be propagated along the structure, it may be appropriate to bear in mind that the minimum propagation field is typically around Hu/2. Therefore if Hu is too high, the applied field strength required for propagation may be of such magnitude that the will arrangement for generating the applied field needed to propagate the solitons would be large in size or power consumption, which may be inappropriate for some implementations. Furthermore, similar considerations also apply to the filed strengths relating to injection of solitons into the stack.

Applying the above mentioned considerations of J* and Hu to the examples above, there now follow some examples of materials properties and illustrations of the behaviours that these provide in a layered structure. Referring first to the Example of FIG. 9, a suitable implementation can be effected by selecting values of Hu for the respective magnetic layers at 50 Oe for the low anisotropy layer and 100 Oe for the high anisotropy layer. Herein all field strengths are given in Oersteds (Oe). To consider these in SI units, a conversion can be effected at 1 Oe=1000/4π(≈79.5774715) ampere-turns per meter of flux path. In this example, the coupling strength J* for the parallel coupling for the reset region is set to be 50 Oe and the coupling strength J* for the antiparallel coupling region is set to be −50 Oe.

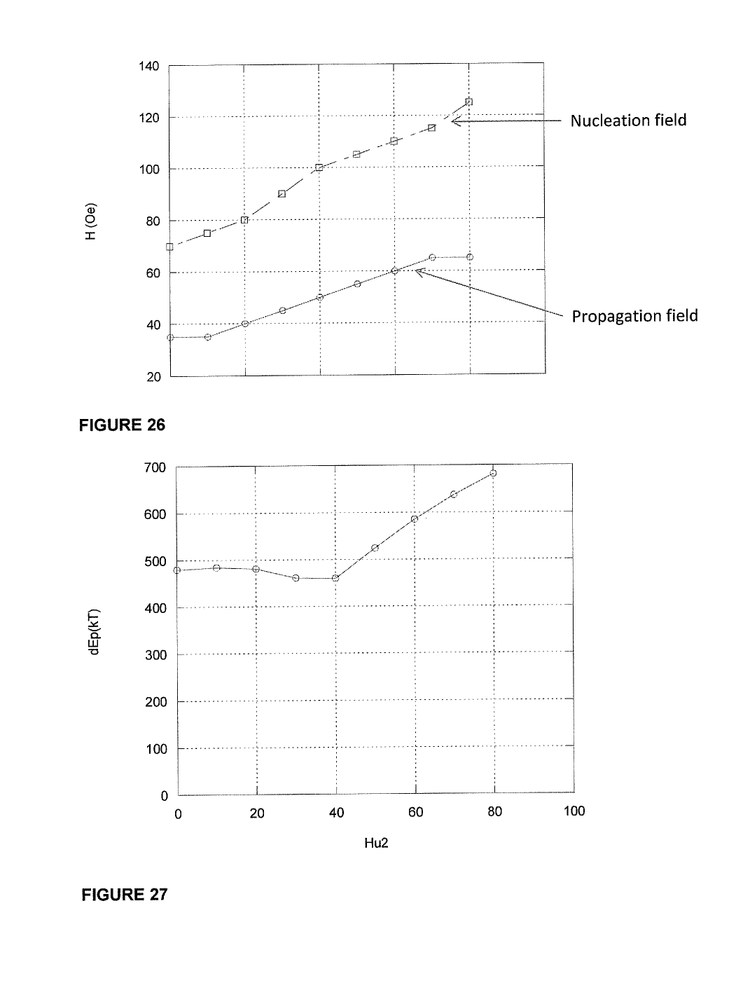

Examples of the operating margin and stability for a period-2 structure such as that of FIG. 9 made of alternating high and low anisotropy layers with alternating parallel and anti-parallel coupling are shown in FIGS. 26 and 27. FIG. 26 shows the propagation and nucleation fields and FIG. 27 shows the propagation energy barrier (ΔEp or dEp) for a physical repeat period-2 structure comprising Hu1, Hu2, Hu1, Hu2 . . . anisotropy variation. For these figures, Hu1 (the higher anisotropy)=100 Oe. Hu2 (the lower anisotropy, also in Oe) is on the x-axis of the graphs (the x-axis labels of FIG. 27 apply also to FIG. 26). The interaction field J* between layers is +/−50 Oe (positive for parallel coupled, negative for antiparallel coupled). The energy barrier is calculated for a circular disk 1 μm in diameter and 1 nm thick and is expressed in units of kT where T=300K.

Thus it is seen that the values of either or both of the anisotropies can be altered, as can the coupling strength and as can the physical dimensions of the layers. For example, Hu1 can lie in the range of around 20 to 200 Oe, Hu2 (smaller than Hu1) can lie in the range of around zero to 190 Oe. It is believed that in some examples a separation of around 10 Oe or more may be appropriate to facilitate reliable operation. The coupling strength can lie in the range of around 10 to 200 Oe. Propagation field strengths can lie in the range of around 10 to 200 Oe. In the propagation example of FIG. 13, which illustrates an example propagation in a device of FIG. 9, the values are Hu1=100 Oe, Hu2=50 Oe, J*−ve=−50 Oe, J*−ve=50 Oe. Applied field amplitude=70 Oe. Figures outside these ranges are also possible.

Referring now to the example of FIG. 10, the selected values of Hu for the respective magnetic layers can be at 50 Oe for the low anisotropy layer, 75 Oe for the medium anisotropy layer and 100 Oe for the high anisotropy layer. In this example, the coupling strength J* for the parallel coupling for the reset region is set to be 50 Oe and the coupling strength J* for each of the antiparallel couplings is set to be −50 Oe. In addition, the values of any or all of the anisotropies can be altered, as can the coupling strength and as can the physical dimensions of the layers. For example, Hu1 can lie in the range of around 20 to 200 Oe, Hu2 (smaller than Hu1) can lie in the range of around 10 to 190 Oe, and Hu3 (smaller than Hu2) can lie in the range of around zero to 180 Oe. It is believed that in some examples a separation of around 10 Oe or more may be appropriate to facilitate reliable operation. The coupling strength can lie in the range of around 10 to 200 Oe. Propagation field strengths can lie in the range of around 10 to 200 Oe. Figures outside these ranges are also possible.

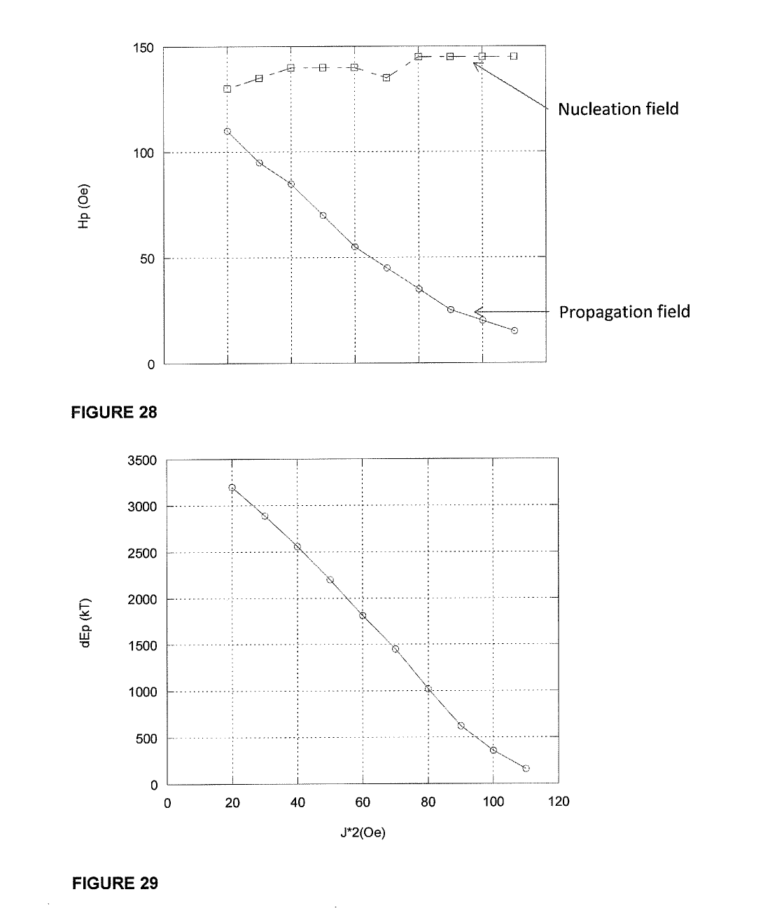

Examples of the operating margin and stability for a period-3 structure such as that of FIG. 14 made of constant anisotropy layers with alternating parallel and anti-parallel coupling and varying coupling strength magnitudes are shown in FIGS. 28 and 29. FIG. 28 shows the propagation and nucleation fields and FIG. 29 shows the propagation energy barrier (ΔEp or dEp) for a physical repeat period-3 structure comprising J1*,J2*,J3*,J1* . . . coupling strength variation. For these figures, J1*=−120 Oe (− means antiparallel), J3*=+120 Oe (+ means parallel), J2* is on the x-axis of the graphs (the x-axis labels of FIG. 29 apply also to FIG. 28). The anisotropy of each layer Hu=100. The energy barrier is calculated for a circular disk 1 μm in diameter and 1 nm thick and is expressed in units of kT where T=300K.

Thus it is seen that the values of any or all of the couplings can be altered, as can the layer anisotropy and as can the physical dimensions of the layers. For example, J1* can lie in the range of around −20 to −200 Oe, J2* (smaller than J1*) can lie in the range of around +/−10 to +/−190 Oe, and J3* can lie in the range of around +20 to +200 Oe. It is believed that in some examples a separation of around 10 Oe or more may be appropriate to facilitate reliable operation. The anisotropy can lie in the range of around 10 to 200 Oe. Propagation field strengths can lie in the range of around 10 to 200 Oe. In the propagation example of FIG. 16, which illustrates an example propagation in a device of FIG. 14, the values are J1*=−120 Oe, J2*=−70 Oe, J3*=+120 Oe, Hu=100 Oe. Applied field amplitude =70 Oe. Figures outside these ranges are also possible.

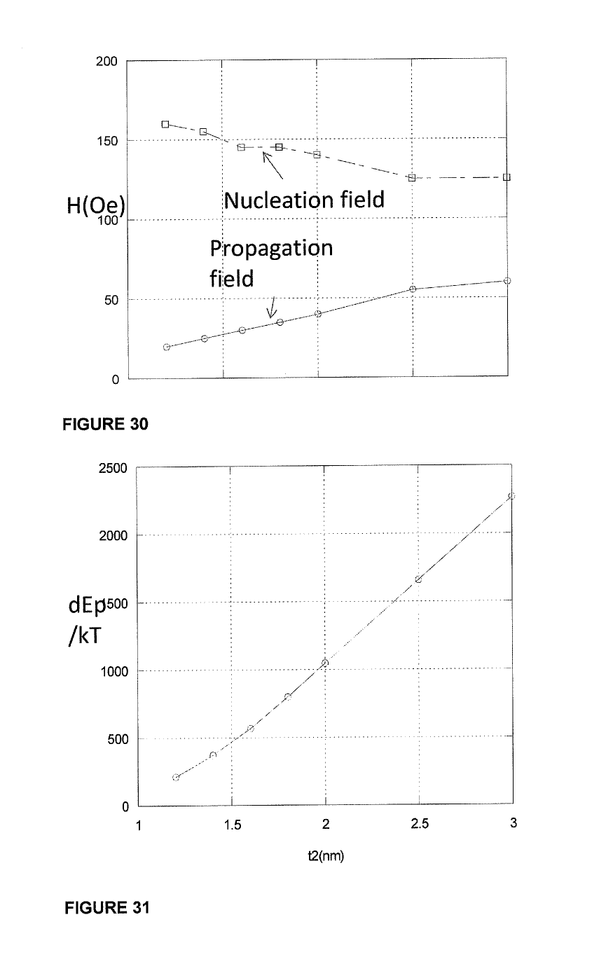

Examples of the operating margin and stability for a period-3 structure such as that of FIG. 17 made of constant anisotropy layers with constant magnitude parallel and anti-parallel coupling and varying layer thicknesses are shown in FIGS. 30 and 31. FIG. 30 shows the propagation and nucleation fields and FIG. 31 shows the propagation energy barrier (ΔEp or dEp) for a physical repeat period-2 structure comprising t1, t2, t1 . . . layer thickness variation. For these figures, t1=1 nm, Hu=100 Oe, J1=−100 Oe-nm; J2=+100 Oe-nm. t2 is on the x-axis of the graphs (the x-axis labels of FIG. 31 apply also to FIG. 30). The energy barrier is calculated for a circular disk 1 μm in diameter and is expressed in units of kT where T=300K.

In addition, the values of either or both of the thicknesses can be altered, as can the coupling strength and as can the anisotropies of the layers. For example, t1 can lie in the range of around 0.5 to around 10 nm and t2 (larger than t1) can lie in the range of around 0.6 to around 11 nm. Hu can lie in the range of around 10 to 200 Oe. It is believed that in some examples a separation of around 10 Oe or more may be appropriate to facilitate reliable operation. The coupling strength can lie in the range of around 10 to 200 Oe. Propagation field strengths can lie in the range of around 10 to 200 Oe. Figures outside these ranges are also possible.

Referring now to the example of FIG. 24, the high anisotropy layer could be [Co(0.47 nm)Pd(0.9 nm)]4 and the low anisotropy layer could be [Co(0.6 nm)Pd(0.9 nm)]4, i.e. the anisotropy is adjusted by changing the Co layer thickness slightly in the ordered alloy. In this example, reducing the Co thickness within the multilayer structure from 0.6 nm to 0.47 nm approximately doubles the anisotropy as between the high and low anisotropy layers. The parallel coupling layer could be 1.5 nm Ru and the antiparallel coupling layer could be 1.0 nm Ru. It is believed that these values can be altered. For example, the ordered alloy layers could have any number from 2 to 10 repeat layers. Figures outside these ranges are also possible.

Referring now to the example of FIG. 25 the thick magnetic layer could be [Co(0.6 nm)Pd(0.9 nm)]4 and the thin layer could be [Co(0.6 nm)Pd(0.9 nm)]3, i.e. the resulting net switching field is altered by changing the number of repeats within the ordered alloy. The parallel coupling layer could be 1.5 nm Ru and the antiparallel coupling layer could be 1.0 nm Ru. It is believed that these values can be altered. For example, the ordered thin alloy layers could have any number from 2 to 10 repeat layers and the thick ordered allow layers could have any number from 3 to 11 repeat layers. Figures outside these ranges are also possible.

As mentioned above, actual materials and dimensions to achieve a given set of field strengths may vary considerably depending on not just the materials chose but also the fabrication technique. Thus although example materials and dimensions are given in the above examples, it will be appreciated that the teaching of the present disclosure extends beyond those examples of particular values to encompass operable structures consistent with the principles and spirit of the present disclosure.

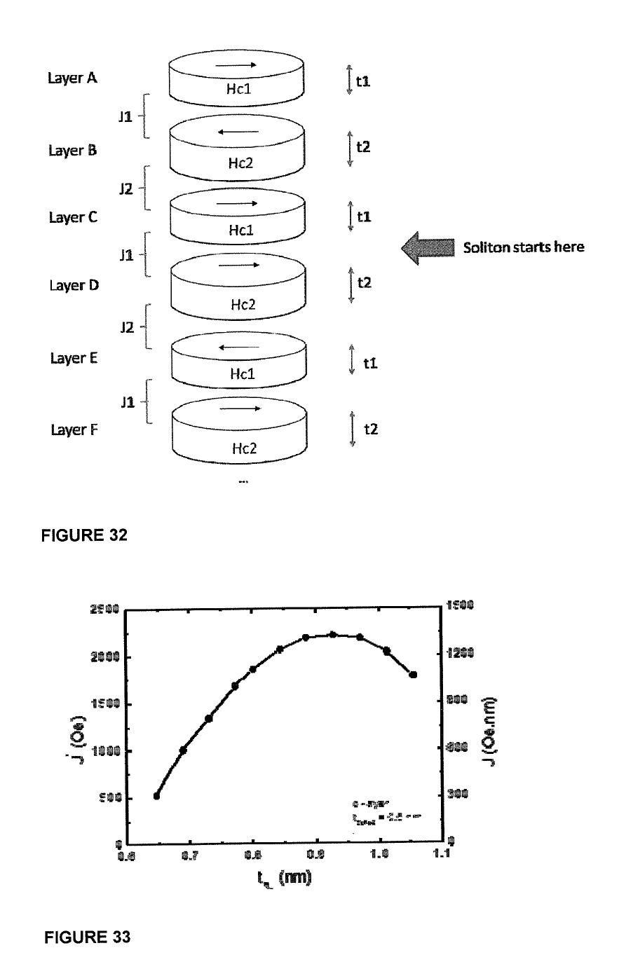

Another example of an approach to implement a structure having a managed profile of resulting net switching field is illustrated with respect to FIGS. 32 to 35.

An example structure, as illustrated in FIG. 32, has layer thicknesses that alternate between t1 and t2 and interlayer areal energy density of coupling that alternates between J1 and J2. As the skilled reader will understand, J* will also change, but in a more complex manner as t is also changing. It is also possible to have the coercivity of each layer (which is related directed to the anisotropy of the layer) alternate between Hc1 and Hc2. Thus the arrangement of FIG. 32 shows a generalised layer structure of alternating thickness, coercivity and exchange coupling. All exchange couplings are assumed to be negative, i.e. preferring anti-parallel alignment. Although FIG. 32 illustrates the easy-axis of anisotropy of the magnetic layers being in-plane, the same is true of materials and structures with an out of plane easy axis of anisotropy.

To illustrate the operation of this example, an assumption is made that the easy-axis switching of the magnetic layers exhibits Brown's Paradox, i.e. the coercivity Hc is less than the anisotropy Hu. This assumption makes the system Ising-like, i.e. the magnetisation orientation is at all times close to the easy axis and phenomena such as spin-flop do not occur. It should be noted that this assumption is not necessary for a functioning device, rather the assumption is made to enable the concept to be illustrated by way of simple algebra. If the easy-axis switching of the magnetic layers does not exhibit Brown's Paradox, the same system behaviour occurs and the mathematic representations of the system is of increased complexity.

In the present example, both J1 and J2 are negative, i.e. all of the layers are coupled such that antiparallel alignment of layers is energetically preferred. FIG. 32 shows a frustration located between layers C and D. The frustration is seen from the Figure in that layers C and D have parallel magnetisation directions where the structure energetically prefers the magnetisation directions to be antiparallel aligned. The present example provides a managed net switching field profile such that under an oscillating magnetic field directed along the easy axis the soliton moves up the layer structure as oriented in FIG. 32, i.e. towards Layer A.

Due to the presence of the frustration, both layers C and D experience a reduced local exchange field since the presence of the frustration causes the exchange fields from their nearest neighbours act in opposite directions.

As will be seen from the following, the frustration is again a topological soliton as the frustration is mobile (by reversing the magnetisation of a frustrated disk); localised (away from the frustration each disk is in a stable, low-energy state); and persistent (to remove the frustration, half of the disks in the stack would have to be reversed, equivalent to moving the frustration all the way to one end of the stack and allowing it to fall out of the end). It is a kink soliton as the order parameter changes in passing through the soliton.

For upward (in the orientation shown in FIG. 32) propagation of the frustration, the net switching field of Layer C is less than that of Layer D, i.e.

$${H}_{c}^{C} = {H}_{c 1} + \frac{\vert {J}_{2} \vert}{{t}_{1}} - \frac{\vert {J}_{1} \vert}{{t}_{1}} \\ {H}_{c}^{D} = {H}_{c 2} + \frac{\vert {J}_{2} \vert}{{t}_{2}} - \frac{\vert {J}_{1} \vert}{{t}_{2}} \\ \to {H}_{c 1} - {H}_{c 2} + \frac{\vert {J}_{2} \vert}{{t}_{1}} - \frac{\vert {J}_{1} \vert}{{t}_{1}} + \frac{\vert {J}_{1} \vert}{{t}_{2}} - \frac{\vert {J}_{2} \vert}{{t}_{2}} < 0 \qquad [ 1 ]$$

Once Layer C has switched, the soliton will lie between layer B and layer C. So as to maintain the propagation direction, on the next half cycle of applied field layer B switches before layer C and so layer C will have B lower net switching field than layer C, i.e.

$${H}_{c}^{B} = {H}_{c 2} - \frac{\vert {J}_{2} \vert}{{t}_{2}} + \frac{\vert {J}_{1} \vert}{{t}_{2}} \\ {H}_{c}^{C} = {H}_{c 1} - \frac{\vert {J}_{2} \vert}{{t}_{1}} + \frac{\vert {J}_{1} \vert}{{t}_{1}} \\ \to {H}_{c 2} - {H}_{c 1} + \frac{\vert {J}_{1} \vert}{{t}_{2}} - \frac{\vert {J}_{1} \vert}{{t}_{1}} + \frac{\vert {J}_{2} \vert}{{t}_{1}} - \frac{\vert {J}_{2} \vert}{{t}_{2}} < 0 \qquad [ 2 ]$$

There is no need to then consider the movement of the soliton from layers B & C to layers A & B since this has the identical conditions as moving from layers C & D to layers B & C, i.e. once equations [1] and [2] are satisfied then the soliton will propagate unidirectionally up the entire repeated layer structure.

Considering now the case where H_{c1}=H_{c2}, a Taylor expansion of [1] and [2] can be made to express these two requirements as a single equation:

$$\frac{Δ t}{{t}_{0}^{2}} ( \vert {J}_{2} \vert - \vert {J}_{1} \vert ) < 0 \qquad [ 3 ]$$

where t₀ is the average magnetic layer thickness and Δt is the difference in thickness between layers, i.e the layer thicknesses alternate between t₀−Δt/2 and t₀+Δt/2.

Typical values that can be achieved in real material systems are: t₁=0.6 nm, t₂=0.75 nm; J1=−800 Oe-nm (antiparallel); J2=−400 Oe-nm (antiparallel); Hc1=Hc2=240 Oe. These values would be achieved using Co₆₀Fe₂₀B₂₀ for the magnetic layers and ruthenium as the RKKY coupling layer and would result in an out-of-plane anisotropy easy axis. J can be tuned by changing the thickness of the Ru layer according to the experimental values shown in FIG. 33 which shows that to achieve J1 a ruthenium thickness of 0.68 nm is needed and to achieve J2 a ruthenium thickness of 0.73 nm is needed. Although the difference in thickness between these two values is small (approximately half an atom average thickness) this degree of layer thickness control is straightforwardly achieved using modern sputter deposition technology. In FIG. 33, the left hand y-axis shows J* (measured in Oe), the right hand y-axis shows J (measured in Oe.nm) and the x-axis shows the thickness of the Ru layer (measured in nm). In the bi-layer structure used to obtain the results of FIG. 33, the thickness of the magnetic CoFeB later is 0.6 nm.

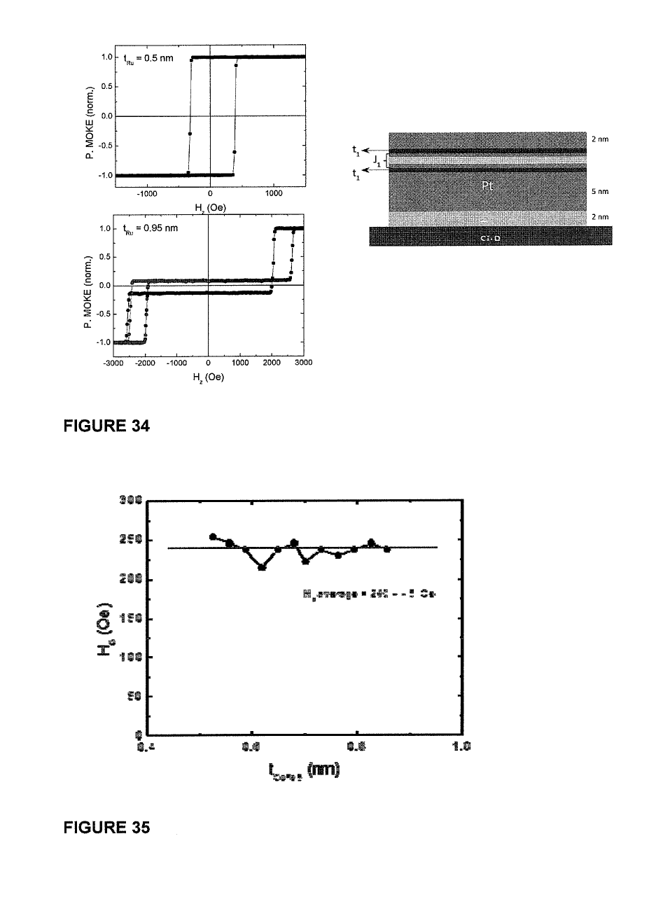

As an example, FIG. 34 shows experimental data hysteresis loops obtained by MOKE from two 0.6 nm thick CoFeB layers coupled by different thicknesses of Ru. The upper case (having an Ru layer thickness of 0.5 nm) shows the two layers switching together, which indicates either no coupling or parallel coupling (i.e. not anti-parallel coupling). The lower case (having an Ru layer thickness of 0.95 nm) shows the two layers switching separately and with a strong exchange field splitting the loop. In this case strong antiparallel coupling exists, as evidenced by the different number of transitions in the hysteresis loops.

For this material system, Hc is found to be largely independent of the magnetic layer thickness (at least across the range of thicknesses considered here) and so the approximation used to arrive at equation [3] is valid. This is shown in the experimental data shown in FIG. 35 which plots coercivity (H_{c} measured in Oe) as a function of CoFeB layer thickness showing independence. The average value of Hₑ illustrated in the plot is 240 +/−5 Oe.

Thus there have now been described a number of example structures having different physical dimensional and materials properties which are all operable to implement a managed profile of resulting net switching field to enable directional propagation of solitons therethrough as well as approaches for operating such structures to carry data.

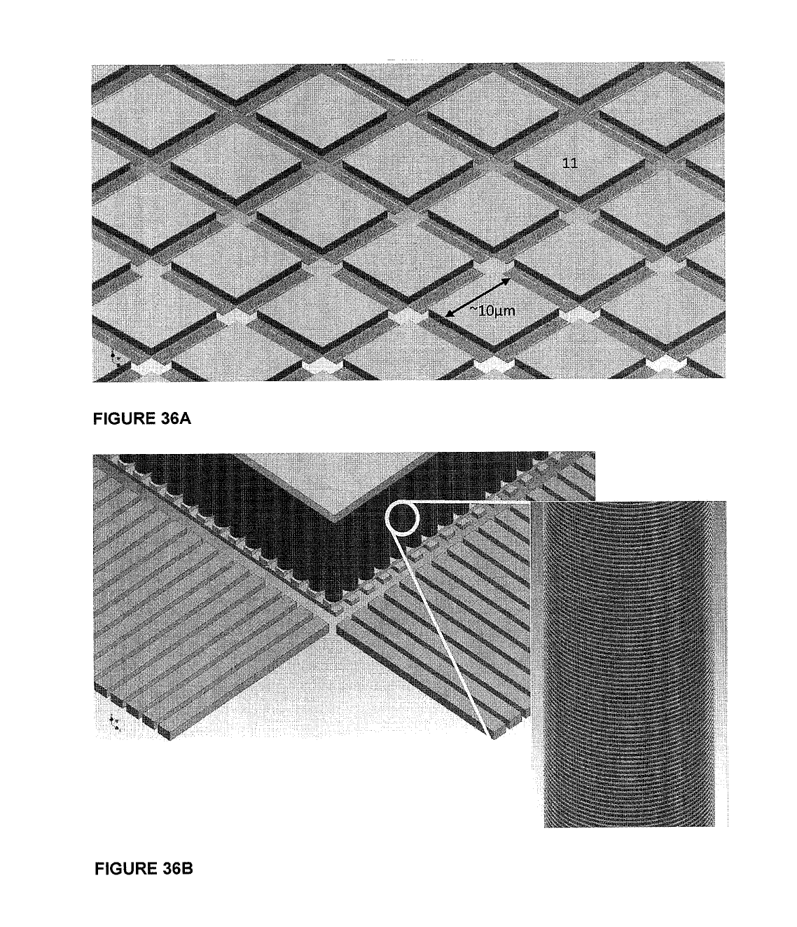

FIGS. 36A and 36B show examples of an arrangement by means of which a number of structures as described above can be set to work together to form a memory element array.

FIG. 36A shows schematically a large device in which an array of memory circuits 11 are arranged together on a common support member to provide a memory device. Each memory circuit includes a number of data storage layered structures as illustrated in FIG. 36B. FIG. 36B shows an enlarged view of one corner of one of the memory circuits 11 of FIG. 36A. As is shown in the further enlarged section of FIG. 36B, each columnar structure is a layered structure comprising a number of layers. In this example, the layered structures are depicted as columns or stacks. Most of the device can be formed, for example, using a Back End Of Line (BEOL) process on a CMOS chip. The number of repeat layers in each stack governs the maximum capacity in terms of number of data bits per stack. As mentioned above, a soliton density of up to approaching around one soliton per three physical magnetic layers can be achieved by arrangements of the present examples. Although small height stacks can be used, it will be understood that taller stacks provide greater storage capacity per chip area. Therefore, in various examples, the stacks may have as few as 100 magnetic layers (providing a maximum data density of approximately 25 to 30 stored bits per stack). In other examples, each stack may have 1,000, 10,000 or 100,000 magnetic layers (for data densities of up to around 250 to 300, 2500 to 3000 or 25000 to 30000 bits per stack respectively). Where each stack has of the order of 10,000 to 100,000 magnetic layers, a suitable high aspect ratio fabrication process may be used.

At one end of each stack there is a soliton injector device which converts electrical signals from the CMOS logic of the chip into a stream of solitons representing a serial data stream that is to be stored in the stack. At the other end of the stack there is a detector device which is used during data retrieval to convert the magnetic state at the end of the stack back into electrical pulses. An external applied field generator can be operated to apply a magnetic field which acts along the length each stack and which can therefore drive solitons along each stack.

In some examples, a pair of stacks can be linked such that anything read from one stack is automatically reinserted into the other stack. This arrangement provides for a pair of stacks to be operated as a single memory element. This can be achieved by electronically linking the read/write circuitry for the two stacks such that as solitons are propagated out of one stack in order to read the data encoded therein, the same data is rewritten into the other stack by insertion of solitons encoding the same data. An alternative arrangement to achieve the same effect has the output of a stack linked to its own input so that data is automatically rewritten into the stack as it is read from the output.

The data storage device can be implemented with either a global field generator or with local field generators for individual ones or groups of stacks. Where a field is generated which affects more than one stack, any use of the field to propagate solitons up or down those stacks will affect all of the driven stacks at once, leading to parallel propagation of solitons in the affected stacks.

For data read and write the data can be stored to each individual stack at a rate based upon the frequency of oscillation of the magnetic field. The total data rate of a data storage device incorporating multiple stacks can be further increased by reading/writing in parallel to multiple stacks. Such parallel writing (and associated reading) can be effected by bulk propagation of a number of stacks using a common propagation drive. The common propagation drive can include feeding the same drive signal to multiple field generators and/or use of a large field generator that affects multiple stacks at one time.

For generation of the external propagation field, a number of options can be utilised. For a small stack on a conventional bit-line/word-line matrix, the applied field can be applied using low magnitude dephased pulses on these lines. For such arrangements, and for arrangements where this is not technically possible due to the design of the bit-lines and word-lines or the size of the stack, other approaches can be considered.

One efficient way to generate the oscillating magnetic field that propagates solitons through the layered structure is by use of a strip line for structures made from in-plane magnetised materials and by use of a planar coil (for example having approximately 1 turn) for structures made from out of plane magnetised materials. In either case, the strip line or coil would typically be driven by passing a sinusoidal signal or a pulsed signal therethrough.

For in-plane magnetised materials where a strip line is used to generate the propagation field, the strip line would typically be located directly above or below the stacks to be affected by the field generated thereby. In some examples, the strip line could be clad with a magnetic material in order to increase the strength of the emitted field. Details relating to such cladding may be found in WO2003/043020.

For out-of-plane magnetised materials, the planar coil may typically be located to the side of the stacks to be affected by the field generated thereby. The coil could be placed to the side and above or below the stacks. It is believed that the driving effect of the field from the planar coil is provided when there is an angle between the coil and the location at which the field is to act. In some examples, there may be provided a number of stacks within the perimeter of a single coil, all of which stacks would then be propagated together by the field generated by the coil. Thus there have now been described a number of examples for generation of an oscillating magnetic field acting across the layers of a layered structure in order to drive the propagation of solitons through the layered structure.

Thus a number of examples of a device for field driven propagation of solitons through a layered structure has been provided.

As mentioned above, a data storage device can store data bits by injecting one or more solitons into the layered structure and propagating them along the layered structure. The soliton(s) would then remain in the layered structure until required, at which point it would be propagated through to the other end of the layered structure and detected as it leaves (a First In First Out serial shift register).

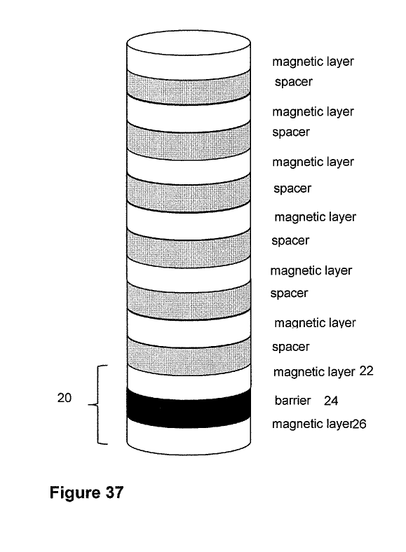

Thus for data storage purposes it may be necessary to inject controllably at one end of the layered structure a sequence of solitons representing the data bits to be stored. Suitable coding mechanisms that could be used have been discussed above. In the present examples, it is assumed to be most likely that the data sequence for storage will begin in electrical form, and that this is then converted to magnetic form by some injector device at one end of the layered structure. An example of a suitable injector device will now be discussed with reference to FIG. 37.

FIG. 37 shows an example of an injector device based upon use of a tunnel junction. The tunnel barrier structure 20 of this example has two magnetic layers 22 and 26 separated by a barrier layer 24. Further detail of using a tunnel barrier structure for changing the state of a magnetic layer is given in Zhitao, D. et al, Hournal of Applied Physics 99, 08G510 2006.

In the described arrangements using a tunnel barrier injection system, the soliton detection arrangement is omitted for simplicity of understanding. A separate detection arrangement as discussed below can be provided at the other end of the layered structure.

An example reader structure based upon a Tunnel Magneto Resistance (TMR) structure will now be described. Such a structure provides a high usable magnitude of the read-out signal, thus enabling a high density arrangement of stacks on the circuit which supplies the data to the layered structures (such as CMOS circuit).

In this example the top of the layered structure is isolated from a pinned ferromagnetic layer by a tunnel barrier (e.g. a thin magnesium oxide layer, see, for example, S. S. P. Parkin et al. “Giant tunnelling magnetoresistance at room temperature with MgO (100) tunnel barriers” Nature Materials 3, 862-867 (2004) doi:10.1038/nmat1256) and an electrical current is passed between the top magnetic layer of the layered structure and the pinned ferromagnetic layer via the tunnel barrier. The TMR effect gives a very strong dependence of resistance on the relative orientation of the magnetisation in the two magnetic layers, allowing the magnetic state of the top of the layered structure to be easily detected.

Assuming that the write mechanism also uses a current passing through the relevant layers of the stack, it may be appropriate to pass the current through the entire length of the stack so that both write and read processes can be current based and such that no extra contact layers need be inserted. If using a current passed through the entire stack in order to perform writing and reading, it may be appropriate to perform write and read operations at a slightly different part of the magnetic field cycle in order to separate the current conditions for writing from the current conditions for reading.

Where an approach using an electrical current passing through the whole stack is used, even though many layers of the layered structure are involved in the passage of the electrical current, the electrical resistance is dominated by the tunnel barrier and the spin-dependence of the resistance of the layered structure is dominated by the relative orientation of the magnetisation on either side of the tunnel barrier. Thus the ability to read is not compromised by the large number of soliton holding layers within the structure.

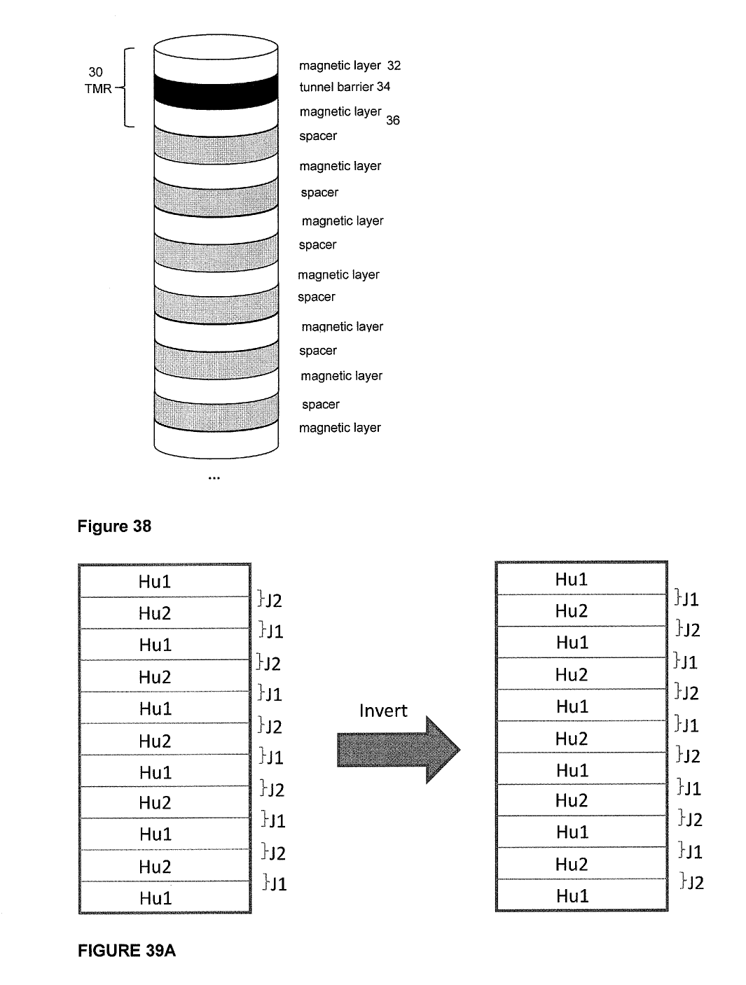

FIG. 38 shows an example implementation of this principle. The TMR structure 30 has a tunnel barrier layer 34 located at the top of the layered structure between the top 32 and second from top 36 magnetic layers in the layered structure. This allows transition detection of a soliton passing through the tunnel barrier.

In the described arrangements using a TMR detection system, the soliton injection arrangement is omitted for simplicity of understanding. A separate injection arrangement as discussed above or below can be provided at the other end of the layered structure.

Thus the use of a tunnel barrier based approach to write solitons into and/or read solitons from a layered structure has now been described. In some examples, tunnel barrier based approaches can be used for both reading and detection elements.

Another approach for an injector is to use a spin valve at the writing end of the layered structure. The spin valve consists of a magnetic layer separated from “first” magnetic layer of the layered structure by a non-magnetic metal layer. The spin valve when operating in a write context uses spin momentum transfer switching in which a current is passed through the spin valve leading to the reversal of the magnetically softer layer, as described in: Katine, J. A. et at Current-driven magnetization reversal and spin-wave excitations in Co/Cu/Co pillars. Phys. Rev. Lett. 84, 3149-3152 (2000).

In the described arrangements using a spin valve write system, the soliton reading arrangement is omitted for simplicity of understanding. A separate reading arrangement as discussed above or below can be provided at the other end of the layered structure.

For a soliton detection element, a spin valve arrangement would be provided at the opposite end of the stack to a writing arrangement. The layer structure of such a reading element could be similar to or the same as that used for writing but the read would be based upon exploiting the giant magnetoresistance effect. The electrical resistance of the spin valve varies according to the alignment of the magnetic layers. The magnetic layers align “up” or “down” depending on an external magnetic field. One of the magnetic layers has higher anisotropy than the other such that the layers switch magnetisation direction at differing applied field strengths. As the external magnetic filed sweeps across the valve, two distinct states can exist, one with the magnetisations of the layers parallel, and one with the magnetisations of the layers antiparallel. As one of the magnetic layers of the spin valve is one of the layers of the soliton maintaining structure, the spin valve can be controlled by application of electrical current through the layers of the spin valve (i.e. along the longitudinal axis of the stack) to set the layer to become parallel or antiparallel aligned to the next magnetic layer up the stack in order to write or not write a soliton on any given field half-cycle or pulse. Thus the use of a spin valve to write solitons into a layered structure has now been described.

In the described arrangements using a spin valve read system, the soliton write arrangement is omitted for simplicity of understanding. A separate writing arrangement as discussed below can be provided at the other end of the layered structure. In some examples, spin valves can be used for both reading and detection elements.

In some examples, a write mechanism may be based upon MRAM technology rather than a spin valve. Thus field induced writing could be implemented by using a single MRAM layer or MRAM pair as a writing element. Other suitable writing mechanisms could include use of a current carrying strip line to pass current pulses through the strip line.

Thus mechanisms and example arrangements for introducing solitons into a layered structure with a managed profile of resulting net switching field have now been described. Also, mechanisms and example arrangements for reading solitons from such a structure have also been described.

Whether or not the writing element is based upon a spin valve or a tunnel barrier and whether or not the reading element is based upon a spin valve or a tunnel barrier, where both the write and read mechanisms are based upon electrical current techniques, an arrangement that can pass an electrical current through the whole stack can be used to control both reading and writing. Where current is provided at a first level, reading occurs, and where current is provided at a second level, writing occurs. As mentioned above, in such an example it may be appropriate to separate the read and write cycles slightly in time so as to provide signal separation to enable the read result to be detected and distinguished from the effects of the write on the current. Also, such separation may in some examples facilitate avoiding a write signal simultaneously causing an as yet unread magnetisation state at the read end from being written over if the write current causes the read element to also act as a write element.

As mentioned above, it is assumed that the basis structure for using a layered structure having solitons introduced thereinto for data storage purposes is as a First In First Out (FIFO) shift register (where reading occurs at the opposite end of the stack to writing). Other options include the pseudo-persistent storage approach mentioned above where two stacks are paired to provide the effect of a read/write element in the middle of the stack or the looped stack approach where the output of the stack is linked to the input of the same stack.

Thus a device can be provided in which data is stored by way of stable frustrations in an order parameter of the magnetisation directions of magnetic layers in a layered structure, which data can be propagated through the structure by a propagation field and which data can be written to and read from the structure by current driven electrical elements.

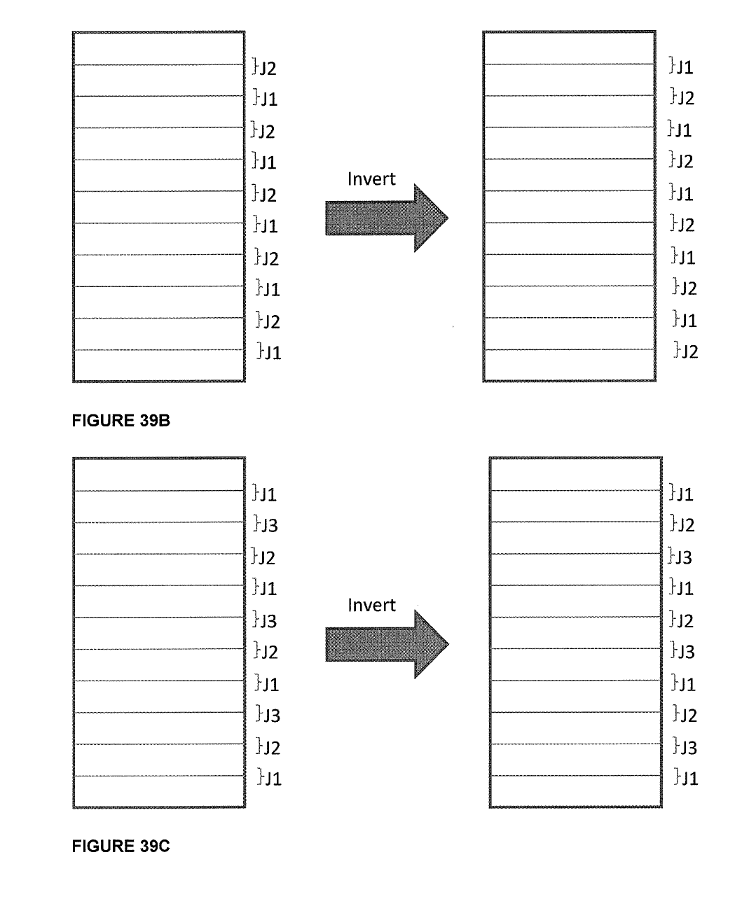

As will be understood from the foregoing, the layered magnetic structures of the present disclosure provide for reliable propagation of solitons in a known direction by providing an inherent propagation direction by way of the properties of the structure. Thus a uni-directional structure can be fabricated to enable a known propagation direction. This known directionality therefore imparts to the structure a non-symmetry of inversion in z (i.e. the longitudinal direction of the layered structure). That is, if a structure can be inverted lengthways and the same applied field in the original direction still causes propagation then there is likely to be significant uncertainty in the reliability of directional propagation. This is illustrated with reference to FIGS. 39A to 39C.

FIG. 39A shows the Hu1,Hu2/J1,J2 structure explained with reference to FIG. 9 above. If this is inverted, it is still possible to determine which way was originally ‘up’. In the original (left hand side of FIG. 39A) moving from an Hu1 layer to an Hu2 layer always goes via a J1 coupling. In the inverted version (right hand side of FIG. 39A), moving from an Hu1 layer to an Hu2 layer now goes via a J2 coupling. Thus this structure type does not possess inversion symmetry and is therefore a candidate for unidirectional propagation.

FIG. 39B shows the same structure except that in this example all of the layers have the same Hu but retain the alternating exchange. In this example there is no way to tell from the structure itself which is up and which is down—the inverted structure is the same as the original. Thus this structure does possess inversion symmetry and therefore cannot be relied upon to propagate unidirectionally.

FIG. 39C shows a modification of the structure of FIG. 35B to make it unidirectional by adding a 3rd coupling strength. In the original (left hand side of FIG. 39C) the couplings always run in the order J1,J2,J3 whereas after inversion (right hand side of FIG. 39C) they run J3,J2,J1. Thus there is again a lack of inversion symmetry and thus the structure is a candidate for unidirectional propagation.

The skilled reader will appreciate that although a lack of inversion symmetry provides for reliable unidirectional propagation, other conditions may also apply in order for unidirectional propagation to occur. For example, where it is desired to perform the “reset” illustrated with reference to FIG. 5 above, it may be appropriate to have both parallel and anti-parallel couplings.

A general principle that may be appropriate to consider is that the structure typically requires at least three sequential elements in order to provide reliable unidirectional propagation. With this in mind the reason the Hu1,Hu2/J1,J2 version works is because the J lies between the two layers and is therefore not associated with just one of them. Thus the sequence of elements Hu1,J1,Hu2 is provided which allows the unidirectionality. An example of a system that doesn't provide such a sequence of at least three elements is Hu1,Hu2/t1, t2, since t1 and Hu1 are associated together and so only form 1 element.

Thus there have been provided some general guiding principles in relation to achieving reliable directionality for propagation of solitons.

It will be appreciated that although the layered structures shown in the examples set out above include only a small number of layers in the layered structure, this is for the purposes of making the figures clear and easily understandable, and, as discussed above, each stack may include a much larger number of layers, for example 100 to 100,000 or even more layers.

Thus a number of examples of layered structures with a managed profile of resulting net switching field enabling the writing of solitons thereinto and the reading of solitons therefrom have now been described. A large number of different data storage devices can be implemented using such structures and including any number of individual layered structures.

It will be appreciated that references to a stack or column refer to specific examples of a suitable layered structure and no particular orientation or aspect ratio of such a layered structure is implied by use of either the term stack or column. It will also be appreciated that reference herein to the “top” or “bottom” of elements such as the stack or column are references to the orientations shown in the Figures and that the devices and arrangements described herein may be inverted or tilted by any angle in any plane without affecting the operation thereof and thus the “top” and “bottom” can be considered as ends according to the particular orientation of the device at a given time.

Thus the presently described examples provide teaching of a layered structure that can be fabricated using materials that exhibit varying strengths of anisotropy, including materials that are magnetised out of plane, and/or epitaxially grown, and/or have shape anisotropy. Thus the individual layers can be small in area, which can provide in some implementations high density utilisation of surface area by allowing many stacks to be placed on a given area of read-write circuitry. Also, thin film layers can be utilised for some implementations, thus providing high volumetric density by increasing the number of solitons (and thus the quantity of data) that can be stored for a given structure height. Also, a linear or rotating propagation field can be used depending on the operational requirements of a particular implementation.

Thus, various arrangements of the present disclosure can provide a field driven thin film layered structure which will support a soliton that: can be propagated by linear oscillating fields as well as rotating fields; keeps the anisotropy direction constant throughout the stack, thus opening up the possibility of using shape anisotropy or epitaxial growth for the anisotropy; works with out of plane magnetised materials as well as in plane magnetised materials, thus opening up the possibility of obtaining very strong anisotropies even in very thin layers; and provides for synchronous propagation of solitons.

The skilled reader will appreciate that the various described arrangements for a column of coupled magnetic discs having a managed profile of resulting net switching field which can maintain an introduced soliton therein and have that soliton propagated therethrough by an externally applied magnetic field and have solitons written thereinto and read therefrom are examples which illustrate the concepts underlying the present disclosure. Various modifications, alterations and equivalents may be employed without departing from the spirit and scope of the present invention.

1-54. (canceled)

55. A structure comprising:
a plurality of groups of magnetic layers, each group comprising three or more sequential physical properties, the plurality of groups arranged successively with the sequential physical properties of one group aligned in the same direction as the sequential physical properties of each adjacent group;
wherein the sequential physical properties of each group provide a resulting net switching field profile along the group that varies from an initial magnetic layer of the group toward a final magnetic layer of the group.

56. The structure of claim 1, wherein the sequential physical properties include one or more selected from the group comprising: anisotropy of the magnetic layers; thickness of the magnetic layers; and inter-layer coupling strength.

57. The structure of claim 1, wherein a final magnetic layer of one group and an initial magnetic layer of the adjacent group are parallel coupled.

58. The structure of claim 3, wherein the parallel coupling is provided by one or more selected from the group comprising: direct exchange coupling and indirect exchange coupling.

59. The structure of claim 1, wherein at least one pair of magnetic layers within the group are antiparallel coupled.

60. The structure of claim 5, wherein the antiparallel coupling is provided by one or more selected from the group comprising: indirect exchange coupling and magnetostatic coupling.

61. The structure of claim 1, wherein ones of the magnetic layers are separated by non-magnetic spacer layers.

62. The structure of claim 1, wherein each magnetic layer has an easy axis of anisotropy aligned relative to the plane of the layer at an orientation selected from the group comprising: parallel to the plane of the layer; and perpendicular to the plane of the layer.

63. The structure of claim 1, wherein each group comprises two magnetic layers having differing anisotropies.

64. The structure of claim 1, wherein each group comprises one or more selected from the group comprising: a single graded anisotropy magnetic layer providing at least two sequential physical properties; three or more magnetic layers each having a different anisotropy; three or more magnetic layers wherein the magnitude of the coupling between the magnetic layers varies over the group; and two or more magnetic layers each having a different thickness.

65. The structure of claim 1, wherein the magnetic layers comprise one or more selected from the group comprising: in-plane magnetised material; and out-of-plane magnetised magnetic material.

66. The structure claim 1, operable to maintain therein a plurality of stable transitions of an order parameter of the magnetisation directions of the layers between ones of the magnetic layers.

67. The structure of claim 12, wherein the transitions are solitons.

68. The structure of claim 12, wherein the transitions can be moved within the structure by an applied magnetic field acting through the structure.

69. A state machine comprising a thin film multilayer structure having magnetic layers with resulting net switching field per layer following a profile gradient and antiparallel coupling between ones of the layers, configured to store state information by maintaining therein a stable frustration in an order parameter of magnetic alignments across the layers.

70. The state machine of claim 15, wherein the magnetic layers have non-magnetic spacer layers therebetween.

71. The state machine of claim 15, further comprising magnetic layers with resulting net switching field per layer following an inverse profile gradient dividing two or more regions having the resulting net switching field per layer profile gradient and having parallel coupling therebetween.

72. The state machine of claim 15, wherein the magnetic layers having parallel coupling therebetween have non-magnetic space layers therebetween.

73. The state machine of claim 15, configured as a storage cell of a memory device.

74. A method of shifting information between magnetic layers in a thin film structure, the method comprising:
applying a magnetic field to the thin film structure, the field having a magnitude sufficient to switch the magnetisation direction of a predetermined one of a pair of layers within the thin film structure when that pair of layers holds a frustration between two regions of different magnetisation direction order parameter within the thin film structure.
